(19) United States
(12) Patent Application Publication
(10) Pub. No.: US 2025/0063927 A1
(43) Pub. Date: Feb. 20, 2025

(54) DISPLAY DEVICE

(71) Applicant: Samsung Display Co., LTD., Yongin-si (KR)

(72) Inventor: Kyung Man KIM, Yongin-si (KR)

(21) Appl. No.: 18/746,927

(22) Filed: Jun. 18, 2024

(30) Foreign Application Priority Data
Aug. 16, 2023 (KR) 10-2023-0106692

(51) Int. Cl. H10K 59/80; H10K 59/90

(52) U.S. Cl. CPC H10K 59/8794; H10K 59/90

(57) ABSTRACT

The present disclosure relates to a display device and a semiconductor device. According to one or more embodiments of the disclosure, a display device includes a driving circuit, a display panel above the driving circuit along a first direction, and a heat dissipation layer between the driving circuit and the display panel, and including chambers, and a piezoelectric element in at least one of the chambers the piezoelectric element being configured to be transformed along the first direction or a reverse direction to the first direction.

### CROSS-REFERENCE TO RELATED APPLICATION

The present application claims priority to, and the benefit of, Korean Patent Application No. 10-2023-0106692, filed on Aug. 16, 2023, in the Korean Intellectual Property Office, the entire disclosure of which is incorporated herein by reference.

### BACKGROUND

### 1. Field

The present disclosure relates to a display device and a semiconductor device.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display may suitably provide high-resolution images, for example, images with a resolution of 3000 PPI (Pixels Per Inch) or higher. To this end, an organic light-emitting diode on silicon (OLEDoS), which is a high-resolution small organic light-emitting display device 10, is used as the display device applied to the head mounted display. The OLEDOS is an image display device in which an organic light-emitting diode (OLED) is located on a semiconductor wafer substrate on which a complementary metal oxide semiconductor (CMOS) is located.

### SUMMARY

Aspects of the present disclosure provide a display device capable of reducing the size of a heat dissipation layer and the noise generated during a heat dissipation operation.

According to one or more embodiments of the disclosure, a display device including a driving circuit, a display panel above the driving circuit along a first direction, and a heat dissipation layer between the driving circuit and the display panel, and including chambers, and a piezoelectric element in at least one of the chambers the piezoelectric element being configured to be transformed along the first direction or a reverse direction to the first direction.

The heat dissipation layer may further include a lower plate adjacent to the driving circuit, an upper plate adjacent to the display panel, and an intermediate plate between the lower plate and the upper plate, and defining a through hole.

The chambers may include a first chamber between the lower plate and the intermediate plate, and a second chamber between the intermediate plate and the upper plate.

The lower plate may define a through hole penetrating the lower plate, wherein the heat dissipation layer further includes a first side plate connecting one edge of the lower plate to one edge of the intermediate plate, a second side plate connecting another edge of the lower plate to another edge of the intermediate plate, a third side plate connecting the one edge of the intermediate plate to one edge of the upper plate, and an opening between the other edge of the intermediate plate and another edge of the upper plate.

The piezoelectric element may overlap the through hole of the intermediate plate.

The heat dissipation layer may further include a support in at least one of the chambers to support the piezoelectric element.

The support may define a through hole penetrating the support in a second direction substantially perpendicular to the first direction.

The display device may further include a heat conduction layer between the display panel and the heat dissipation layer.

The display device may further include a metal layer between the heat conduction layer and the heat dissipation layer.

The display device may further include a circuit board between the driving circuit and the heat dissipation layer.

The heat dissipation layer may further include a first protrusion defined by the lower plate in the first chamber, and a second protrusion defined by the upper plate in the second chamber.

The heat dissipation layer may further include a first valve in the first chamber to overlap a through hole of the lower plate, and a second valve in the second chamber to overlap the through hole of the intermediate plate.

The second valve may overlap the piezoelectric element.

The lower plate may include sub-lower plates including different respective materials, wherein the upper plate includes sub-upper plates including different respective materials.

One of the sub-lower plates overlapping the driving circuit may include a metal material, wherein a remaining one or more of the sub-lower plates includes a plastic material, wherein one of the sub-upper plates overlapping the display panel includes a metal material, and wherein a remaining one or more of the sub-upper plates includes a plastic material.

The heat dissipation layer may further include a first side plate connecting another edge of the lower plate to another edge of the intermediate plate, and a second side plate connecting one edge of the intermediate plate to one edge of the upper plate, wherein the heat dissipation layer defines a first opening between one edge of the lower plate and one edge of the intermediate plate, and a second opening between another edge of the intermediate plate and another edge of the upper plate.

The heat dissipation layer may further include a first side plate connecting one edge of the lower plate to one edge of the intermediate plate, a second side plate connecting another edge of the lower plate to another edge of the intermediate plate, and defining a through hole, a third side plate connecting one edge of the intermediate plate to one edge of the upper plate, and a fourth side plate connecting the other edge of the intermediate plate to another edge of the upper plate, and defining a through hole.

The intermediate plate may include a first intermediate plate between the lower plate and the upper plate, and defining a through hole, and a second intermediate plate between the first intermediate plate and the upper plate, and defining a through hole.

The chambers may include a first chamber between the lower plate and the first intermediate plate, a second chamber between the first intermediate plate and the second intermediate plate, and a third chamber between the second intermediate plate and the upper plate.

The heat dissipation layer may further include a first side plate connecting one edge of the lower plate to one edge of the intermediate plate, a second side plate connecting another edge of the first intermediate plate to another edge of the second intermediate plate, a third side plate connecting one edge of the second intermediate plate to one edge of the upper plate, and wherein the heat dissipation layer defines a first opening between another edge of the lower plate and the other edge of the first intermediate plate, a second opening between one edge of the first intermediate plate and the one edge of the second intermediate plate, and a third opening between the other edge of the second intermediate plate and another edge of the upper plate.

The piezoelectric element may be connected to an external power supply.

The piezoelectric element may be connected to the driving circuit.

According to the display device of the present disclosure, it is possible to reduce both the size of the heat dissipation layer and the noise generated during the heat dissipation operation.

The aspects of the present disclosure are not limited to the above-described aspects and other aspects that are not described herein will become apparent to those skilled in the art from the following description.

### BRIEF DESCRIPTION OF DRAWINGS

The above and other aspects of the present disclosure will become more apparent by describing in detail embodiments thereof with reference to the attached drawings, in which:

FIG. 1 is an exploded perspective view showing a display device according to one or more embodiments;

FIG. 2 is a layout diagram illustrating an example of the display panel shown in FIG. 1;

FIG. 3 is a block diagram illustrating a display device according to one or more embodiments;

FIG. 4 is an equivalent circuit diagram of a first pixel according to one or more embodiments;

FIG. 5 is a layout view illustrating pixels of a display area according to one or more embodiments;

FIG. 6 is a cross-sectional view illustrating an example of the display device taken along the line A-A′ of FIG. 5;

FIG. 7 is a perspective view illustrating a head mounted display device according to one or more embodiments;

FIG. 8 is an exploded perspective view illustrating an example of the head mounted display device of FIG. 7;

FIG. 9 is a perspective view illustrating a head mounted display device according to one or more embodiments;

FIG. 10 is a cross-sectional view of the display device according to one or more embodiments;

FIG. 11 is a plan view of a piezoelectric element, a support and a through hole of part A of FIG. 10;

FIG. 12 is an enlarged cross-sectional view of part A of FIG. 11;

FIG. 13 is a timing diagram of an AC power supplied to the piezoelectric element of FIG. 12;

FIGS. 14 and 15 are diagrams for explaining the operation of the piezoelectric element of FIG. 12;

FIGS. 16 and 17 are diagrams for describing the operation of the display device of FIG. 10;

FIG. 18 is a cross-sectional view of the display device according to one or

more embodiments;

FIG. 19 is a cross-sectional view of the display device according to one or more embodiments;

FIG. 20 is a cross-sectional view of the display device according to one or more embodiments;

FIG. 21 is a cross-sectional view of the display device according to one or more embodiments;

FIG. 22 is a cross-sectional view of the display device according to one or more embodiments;

FIG. 23 is a cross-sectional view of the display device according to one or more embodiments;

FIG. 24 is an exploded plan view of a first valve of FIG. 23;

FIGS. 25 and 26 are diagrams for explaining the operation of the display device of FIG. 23;

FIG. 27 is a cross-sectional view of the display device according to one or more embodiments;

FIG. 28 is a cross-sectional view of the display device according to one or more embodiments;

FIGS. 29 and 30 are diagrams for explaining the operation of the display device of FIG. 28;

FIG. 31 is a cross-sectional view of the display device according to one or more embodiments; and

FIG. 32 is a cross-sectional view of the display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

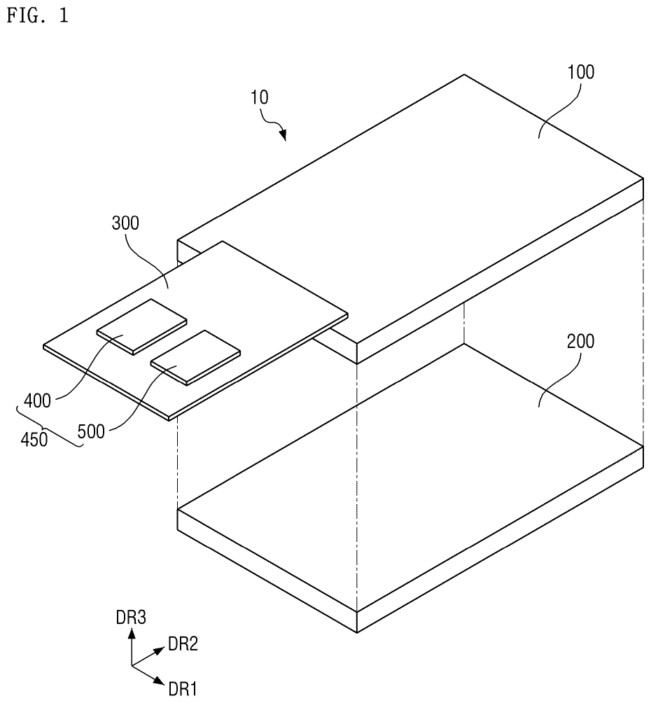

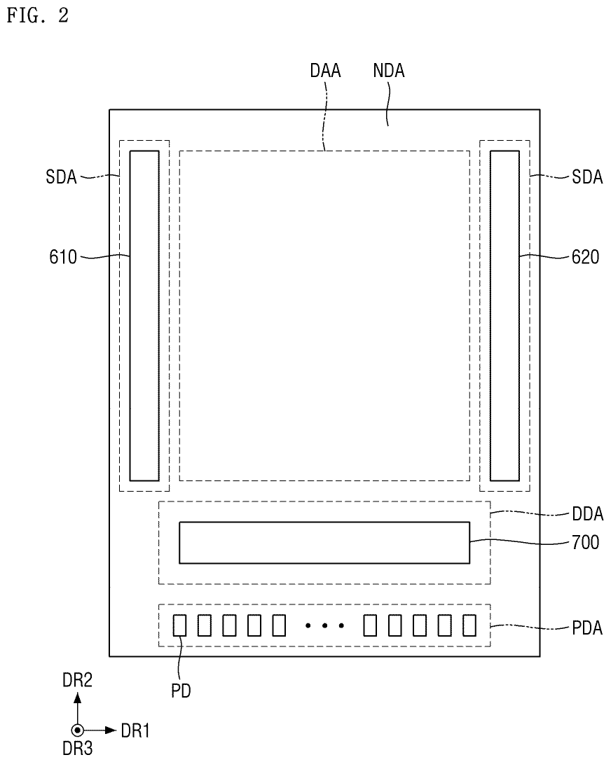

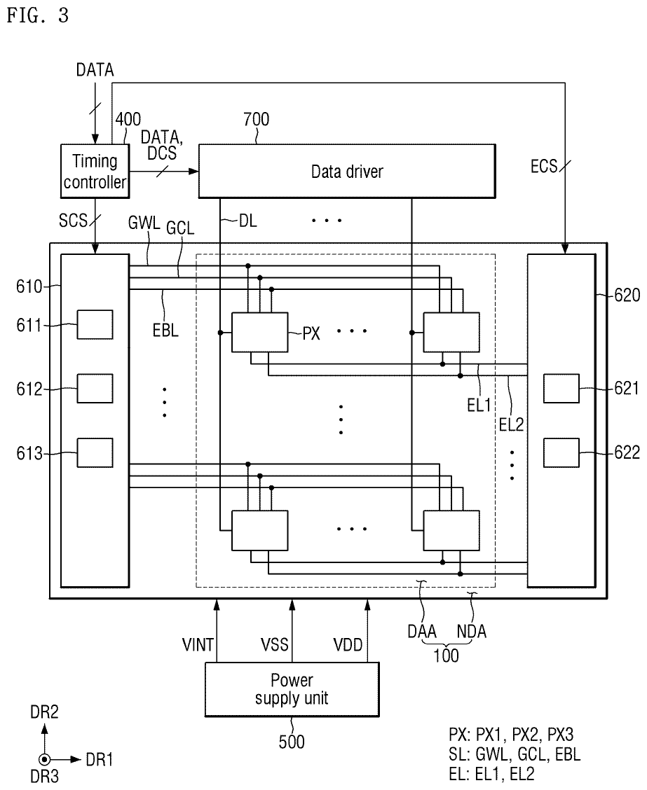

FIG. 1 is an exploded perspective view showing a display device according to one or more embodiments. FIG. 2 is a layout diagram illustrating an example of the display panel shown in FIG. 1. FIG. 3 is a block diagram illustrating a display device according to one or more embodiments.

Referring to FIGS. 1 and 2, a display device 10 according to one or more embodiments is a device for displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display unit of a television, a laptop, a monitor, a billboard, or an Internet-of-Things (IoT) device. Alternatively, the display device 10 may be applied to a smart watch, a watch phone, a head mounted display (HMD) for implementing virtual reality and augmented reality, and the like.

The display device 10 according to one or more embodiments includes a display panel 100, a heat dissipation layer 200, a circuit board 300, and a driving circuit 450.

The display panel 100 may have a planar shape that is similar to a quadrilateral shape. For example, the display panel 100 may have a planar shape that is similar to a quadrilateral shape, having a short side in a first direction DR1, and a long side in a second direction DR2 crossing the first direction DR1. In the display panel 100, a corner where a short side in the first direction DR1 and a long side in the second direction DR2 meet may be right-angled or rounded with a curvature (e.g., predetermined curvature). The planar shape of the display panel 100 is not limited to a rectangular shape, and may be a shape similar to another polygonal shape, a circular shape, or an elliptical shape. The planar shape of the display device 10 may conform to the planar shape of the display panel 100, but the present specification is not limited thereto.

As shown in FIG. 2, the display panel 100 includes a display area DAA for displaying an image, and a non-display area NDA not displaying an image.

As shown in FIG. 3, the display area DAA includes a plurality of pixels PX, a plurality of scan lines SL, which include a plurality of write scan lines GWL, a plurality of control scan lines GCL, and a plurality of bias scan lines GBL, a plurality of emission control lines EL, which include a plurality of first emission control lines EL1 and a plurality of second emission control lines EL2, and a plurality of data lines DL.

Each of the plurality of pixels PX includes a light-emitting element that emits light. The plurality of pixels PX may be arranged in a matrix form in the first direction DR1 and/or the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

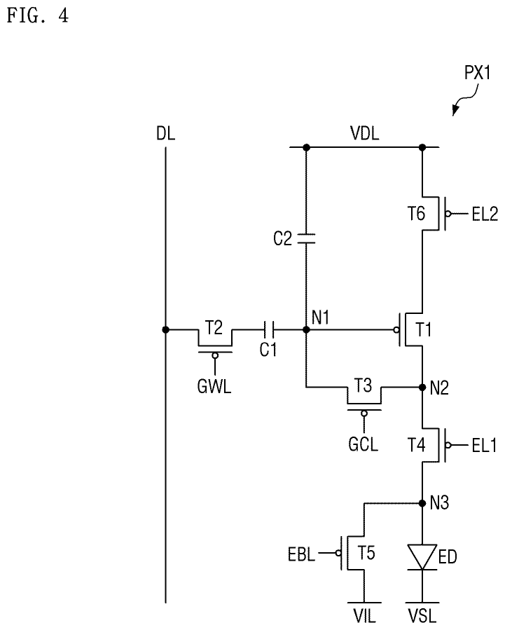

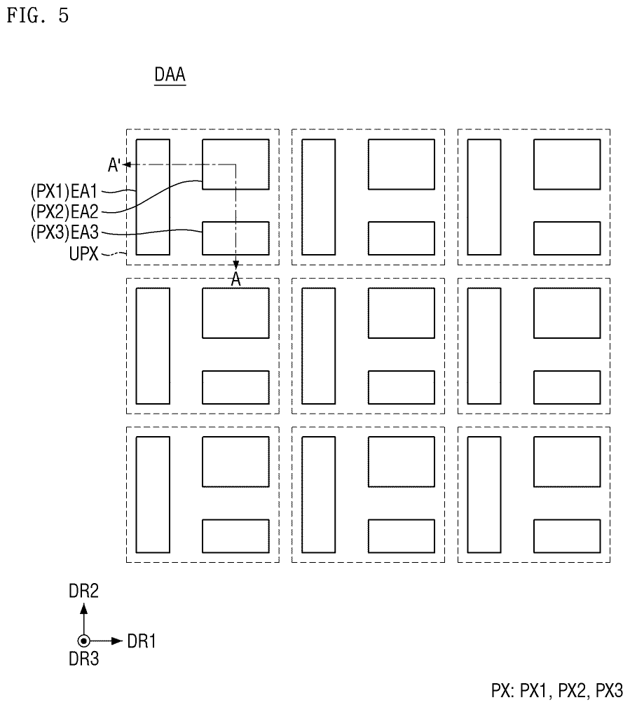

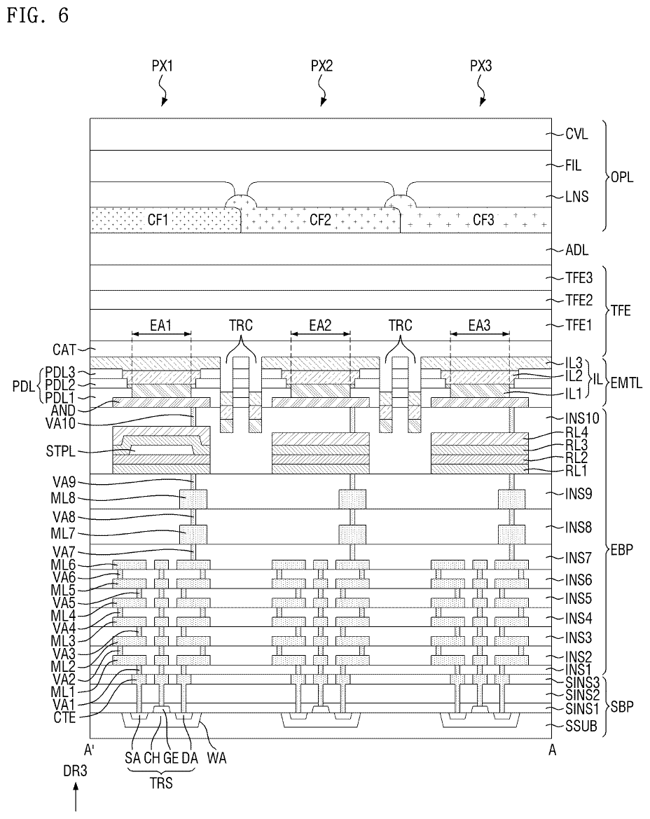

As shown in FIGS. 5 and 6, each of a plurality of unit pixels UPX includes a plurality of pixels PX1, PX2, and PX3. As shown in FIG. 4, the plurality of pixels PX1, PX2, and PX3 may include a plurality of pixel transistors, which may be formed through a semiconductor process, and may be located on (e.g., as used herein, “located on” may mean “located above”) a semiconductor substrate SSUB (see FIG. 6). For example, the plurality of pixel transistors may be formed of a complementary metal oxide semiconductor (CMOS).

Each of the plurality of pixels PX1, PX2, and PX3 may be connected to one of the plurality of write scan lines GWL, one of the plurality of control scan lines GCL, one of the plurality of bias scan lines GBL, one of the plurality of first emission control lines EL1, one of the plurality of second emission control lines EL2, and/or one of the plurality of data lines DL. Each of the plurality of pixels PX1, PX2, and PX3 may receive a data voltage of the data line DL in response to a write scan signal of the write scan line GWL, and may emit light from the light-emitting element according to the data voltage.

The non-display area NDA includes a scan-driving area SDA, a data-driving area DDA, and a pad area PDA.

The scan-driving area SDA may be an area in which a scan driver 610 and an emission driver 620 are located. Although it is illustrated in FIG. 2 that the scan driver 610 is located on the left side of the display area DAA, and that the emission driver 620 is located on the right side of the display area DAA, the present specification is not limited thereto. For example, the scan driver 610 and the emission driver 620 may be located on both the left side and the right side of the display area DAA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 6) through a semiconductor process. For example, the plurality of scan transistors and the plurality of light-emitting transistors may be formed of a CMOS.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from a timing control circuit 400. The write scan signal output unit 611 may generate write scan signals according to the scan-timing control signal SCS of the timing control circuit 400, and may output them sequentially to the write scan lines GWL. The control scan signal output unit 612 may generate control scan signals in response to the scan-timing control signal SCS, and may sequentially output them to the control scan lines GCL. The bias scan signal output unit 613 may generate bias scan signals according to the scan-timing control signal SCS, and may output them sequentially to bias scan lines EBL.

The emission driver 620 includes a first emission control driver 621 and a second emission control driver 622. Each of the first emission control driver 621 and the second emission control driver 622 may receive the emission-timing control signal ECS from the timing control circuit 400. The first emission control driver 621 may generate first emission control signals according to the emission-timing control signal ECS, and may sequentially output them to first emission control lines EL1. The second emission control driver 622 may generate second emission control signals according to the emission-timing control signal ECS, and may sequentially output them to second emission control lines EL2.

The data-driving area DDA may be an area in which a data driver 700 is located. The data driver 700 may include a plurality of data transistors, and the plurality of data transistors may be formed on the semiconductor substrate SSUB (see FIG. 6) through a semiconductor process. For example, the plurality of data transistors may be formed of a CMOS.

The data driver 700 may receive the digital video data DATA and the data-timing control signal DCS from the timing control circuit 400. The data driver 700 converts the digital video data DATA into analog data voltages according to the data-timing control signal DCS, and outputs the analog data voltages to data lines DL. In this case, the pixels PX1, PX2, and PX3 are selected by the write scan signal of the scan driver 610, and data voltages may be supplied to the selected pixels PX1, PX2, and PX3.

The pad area PDA includes a plurality of pads PD arranged in the first direction DR1. In one or more embodiments, each of the plurality of pads PD may be exposed without being covered by a cover layer CVL (see FIG. 6) and a polarizing plate.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer, such as graphite, silver (Ag), copper (Cu), or aluminum (Al) having relatively high thermal conductivity.

The circuit board 300 may be electrically connected to a plurality of pads PD in a pad area PDA of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent or bendable. In this case, one end of the circuit board 300 may be located on the rear surface of the display panel 100. The one end of the circuit board 300 may be an end that is opposite to the other end of the circuit board 300 that is connected to the plurality of pads PD of the pad area PDA of the display panel 100 by using a conductive adhesive member.

The driving circuit 450 may include a timing control circuit 400 and a power supply circuit 500.

The timing control circuit 400 may receive digital video data and timing signals inputted from the outside. The timing control circuit 400 may generate the scan-timing control signal SCS, the emission-timing control signal ECS, and a data-timing control signal DCS for controlling the display panel 100 in response to the timing signals. The timing control circuit 400 may output the scan-timing control signal SCS to the scan driver 610, and may output the emission-timing control signal ECS to the emission driver 620. The timing control circuit 400 may output the digital video data and the data-timing control signal DCS to the data driver 700.

The power supply circuit 500 may generate a plurality of panel-driving voltages according to a power voltage from the outside. For example, the power supply circuit 500 may generate a first driving voltage VSS, a second driving voltage VDD, and a third driving voltage VINT, and may supply them to the display panel 100. Description of the first driving voltage VSS, the second driving voltage VDD, and the third driving voltage VINT will be provided later with reference to FIG. 4.

Each of the timing control circuit 400 and the power supply circuit 500 may be formed as an integrated circuit (IC), and may be attached to one side of the circuit board 300. The scan-timing control signal SCS, the emission-timing control signal ECS, the digital video data DATA, and the data-timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

The driving circuit 450 may include all of the scan driver 610, the emission driver 620, the data driver 700, the timing control circuit 400, and the power supply circuit 500, or may include only some of them selectively. At this time, the power supply circuit 500 may include a gamma driver, which may provide a value that determines the correlation between the brightness (gray level) of the data signal inputted to the display device and the brightness of the image displayed on a screen. Meanwhile, the gamma driver may be provided separately from the power supply circuit 500, and in this case, the driving circuit 450 may further include the gamma driver in addition to the scan driver 610, the emission driver 620, the data driver 700, the timing control circuit 400, and the power supply circuit 500 described above.

Further, the driving circuit 450 may be located in the circuit area of the non-display area NDA of the display panel 100, similarly to the scan driver 610, the emission driver 620, and the data driver 700. For example, the driving circuit 450 may be located on a silicon substrate, a glass substrate, a polyimide substrate, and the like. In this case, the circuit area may be located between the data-driving area DDA and the pad area PDA.

FIG. 4 is an equivalent circuit diagram of a first pixel according to one or more embodiments.

Referring to FIG. 4, the first pixel PX1 may be connected to the write scan line GWL, the control scan line GCL, the bias scan line EBL, the first emission control line EL1, the second emission control line EL2, and the data line DL. In addition, the first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first pixel PX1 includes a plurality of transistors T1, T2, T3, T4, T5, and T6, a light-emitting element LE, a first capacitor C1, and a second capacitor C2.

The light-emitting element ED emits light according to a driving current flowing through the channel of the first transistor T1. A light emission amount of the light-emitting element ED may be proportional to the driving current. The light-emitting element ED may be located between the fourth transistor T4 and the first driving voltage line VSL. The first electrode of the light-emitting element ED may be connected to the drain electrode of the fourth transistor T4, and the second electrode thereof may be connected to the first driving voltage line VSL. The first electrode of the light-emitting element ED may be an anode electrode, and the second electrode of the light-emitting element ED may be a cathode electrode. The light-emitting element ED may be an organic light-emitting diode including a first electrode, a second electrode, and an organic light-emitting layer located between the first electrode and the second electrode, but the present specification is not limited thereto. For example, the light-emitting element ED may be an inorganic light-emitting element including a first electrode, a second electrode, and an inorganic semiconductor located between the first electrode and the second electrode, in which case the light-emitting element ED may be a micro light-emitting diode.

The first transistor T1 may be a driving transistor that controls a source-drain current (hereinafter referred to as a “driving current”) flowing between the source electrode and the drain electrode thereof according to a voltage applied to the gate electrode thereof. The first transistor T1 includes a gate electrode connected to the first node N1, a source electrode connected to the drain electrode of the sixth transistor T6, and a drain electrode connected to a second node N2.

The second transistor T2 may be located between one electrode of the first capacitor C1 and the data line DL. The second transistor T2 is turned on by the write scan signal of the write scan line GWL to connect the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be located between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor ST4 is turned on by the first emission control signal of the first emission control line EL1 to connect the second node N2 to the third node N3. Accordingly, the driving current of the first transistor T1 may be supplied to the light-emitting element ED. The fourth transistor T4 includes a gate electrode connected to the first emission control line EL1, a source electrode connected to the second node N2, and a drain electrode connected to the third node N3.

The fifth transistor T5 may be located between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light-emitting element ED. The fifth transistor T5 includes a gate electrode connected to the bias scan line EBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2, and the other electrode connected to the first node N1.

The second capacitor C2 is formed between the gate electrode of the first transistor T1 and the second driving voltage line VDL. The second capacitor C2 includes one electrode connected to the gate electrode of the first transistor T1, and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element ED.

Each of the first to sixth transistors T1, T2, T3, T4, T5, and T6 may be a metal-oxide-semiconductor field effect transistor (MOSFET). For example, each of the first to sixth transistors T1, T2, T3, T4, T5, and T6 may be a P-type MOSFET, but the present specification is not limited thereto. Each of the first to sixth transistors T1, T2, T3, T4, T5, and T6 may be an N-type MOSFET. Alternatively, some of the first to sixth transistors T1, T2, T3, T4, T5, and/or T6 may be P-type MOSFETs, and the remaining transistor(s) may be an N-type MOSFET.

Although it is illustrated in FIG. 4 that the first pixel PX1 includes the six transistors T1, T2, T3, T4, T5, and T6 and the two capacitors C1 and C2, it should be noted that the equivalent circuit diagram of the first pixel PX1 is not limited to the example shown in FIG. 4. For example, the number of the transistors and the number of the capacitors of the first pixel PX1 are not limited to the example shown in FIG. 4.

In addition, the equivalent circuit diagram of the second pixel PX2 and the equivalent circuit diagram of the third pixel PX3 may be substantially the same as the equivalent circuit diagram of the first pixel PX1 described in conjunction with FIG. 4. Thus, in the present specification, description of the equivalent circuit diagram of the second pixel PX2 and the equivalent circuit diagram of the third pixel PX3 will be omitted.

FIG. 5 is a layout view illustrating pixels of a display area according to one or more embodiments.

Referring to FIG. 5, each of the plurality of pixels PX includes a first emission area EA1 as an emission area of the first pixel PX1, a second emission area EA2 as an emission area of the second pixel PX2, and a third emission area EA3 as an emission area of the third pixel PX3.

Each of the first emission area EA1, the second emission area EA2, and the third emission area EA3 may have, in plan view, a quadrilateral shape, such as a rectangle, a square, or a diamond. For example, the first emission area EA1 may have a rectangular shape, in plan view, having a short side in the first direction DR1, and a long side in the second direction DR2. In addition, each of the second emission area EA2 and the third emission area EA3 may have a rectangular shape, in plan view, having a long side in the first direction DR1, and a short side in the second direction DR2.

The length of the first emission area EA1 in the first direction DR1 may be less than the length of the second emission area EA2 in the first direction DR1, and may be less than the length of the third emission area EA3 in the first direction DR1. The length of the second emission area EA2 in the first direction DR1 and the length of the third emission area EA3 in the first direction DR1 may be substantially the same.

The length of the first emission area EA1 in the second direction DR2 may be larger than the sum of the length of the second emission area EA2 in the second direction DR2 and the length of the third emission area EA3 in the second direction DR2. The length of the second emission area EA2 in the second direction DR2 may be less than the length of the third emission area EA3 in the second direction DR2.

Although it is illustrated in FIG. 5 that each of the first emission area EA1, the second emission area EA2, and the third emission area EA3 has a rectangular shape in plan view, the present specification is not limited thereto. For example, each of the first emission area EA1, the second emission area EA2, and the third emission area EA3 may have a polygonal shape other than a quadrilateral shape, a circular shape, or an elliptical shape in plan view.

In each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

The first emission area EA1 may emit light of a first color, the second emission area EA2 may emit light of a second color, and the third pixel PX3 may emit light of a third color. Here, the first color light may be light of a blue wavelength band, the second color light may be light of a green wavelength band, and the third color light may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is illustrated in FIG. 5 that each of the plurality of pixels PX includes three emission areas EA1, EA2, and EA3, but the present specification is not limited thereto. For example, each of the plurality of pixels PX may include four emission areas.

In addition, the layout of the emission areas of the plurality of pixels PX is not limited to that illustrated in FIG. 5. For example, the emission areas of the plurality of pixels PX may be arranged in a stripe structure in which the emission areas are arranged in the first direction DR1, a PenTile™/PENTILE™ structure (e.g., a RGBG matrix structure, or an RGBG structure, PENTILE™ being a registered trademark of Samsung Display Co., Ltd., Republic of Korea), in which the emission areas are arranged in a diamond shape, or a hexagonal structure in which the emission areas having, in plan view, a hexagonal shape are arranged.

FIG. 6 is a cross-sectional view illustrating an example of the display device taken along the line A-A′ of FIG. 5.

Referring to FIG. 6, the display panel 100 includes a semiconductor backplane SBP, a light-emitting element backplane EBP, a light-emitting element layer EMTL, an encapsulation layer TFE, an optical layer OPL, the cover layer CVL, and a polarizing plate.

The semiconductor backplane SBP includes the semiconductor substrate SSUB including a plurality of pixel transistors TRS, a plurality of semiconductor insulating layers covering the plurality of pixel transistors TRS, and a plurality of contact terminals CTE electrically connected to the plurality of pixel transistors TRS, respectively. The plurality of pixel transistors TRS may be any of the first to sixth transistors T1, T2, T3, T4, T5, and T6 described with reference to FIG. 4.

The semiconductor substrate SSUB may be a silicon substrate, a germanium substrate, or a silicon-germanium substrate. The semiconductor substrate SSUB may be a substrate doped with first type impurities. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor TRS, a drain region DA corresponding to the drain electrode thereof, and a channel region CH located between the source region SA and the drain region DA.

Each of the source region SA and the drain region DA may be a region doped with first type impurities. A gate electrode GE of the pixel transistor TRS may overlap the well region WA in the third direction DR3. The channel region CH may overlap the gate electrode GE in the third direction DR3. The source region SA may be located on one side of the gate electrode GE, and the drain region SA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having an impurity concentration that is lower than that of the source region SA. The second low-concentration impurity region LDD2 may be a region having an impurity concentration that is lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors TRS may increase, so that the likelihood of punch-through and hot carrier phenomena that might be caused by a short channel may be reduced or prevented.

A first semiconductor insulating layer SINS1 may be located on the semiconductor substrate SSUB. The first semiconductor insulating layer SINS1 may be formed of silicon carbonitride (SiCN) or a silicon oxide (SiOx)-based inorganic layer, but the present specification is not limited thereto.

A second semiconductor insulating layer SINS2 may be located on the first semiconductor insulating layer SINS1. The second semiconductor insulating layer SINS2 may be formed of a silicon oxide (SiOx)-based inorganic layer, but the present specification is not limited thereto.

The plurality of contact terminals CTE may be located on the second semiconductor insulating layer SINS2. Each of the plurality of contact terminals CTE may be connected to any one of the gate electrode GE, the source region SA, or the drain region DA of each of the pixel transistors TRS through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating layer SINS3 may be located on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the present specification is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that may can be bent or curved.

The light-emitting element backplane EBP includes first to eighth metal layers ML1, ML2, ML3, ML4, ML5, ML6, ML7, and ML8, reflective metal layers RL1, RL2, RL3, and RL4, a plurality of vias VA1, VA2, VA3, VA4, VA5, VA6, VA7, VA8, VA9, and VA10, and a step layer STPL. In addition, the light-emitting element backplane EBP includes a plurality of interlayer insulating layers INS1, INS2, INS3, INS4, INS5, INS6, INS7, INS8, INS9, and INS10 located between the first to sixth metal layers ML1, ML2, ML3, ML4, ML5, and ML6.

The first to eighth metal layers ML1, ML2, ML3, ML4, ML5, ML6, ML7, and ML8 serve to connect the plurality of contact terminals CTE exposed from the semiconductor backplane SBP to thereby implement the circuit of the first pixel PX1 shown in FIG. 4. That is, the first to sixth transistors T1, T2, T3, T4, T5, and T6 are merely formed on the semiconductor backplane SBP, and the connection of the first to sixth transistors T1, T2, T3, T4, T5, and T6 and the first and second capacitors C1 and C2 is accomplished through the first to eighth metal layers ML1, ML2, ML3, ML4, ML5, ML6, ML7, and ML8. In addition, the connection between the drain region corresponding to the drain electrode of the fourth transistor T4, the source region corresponding to the source electrode of the fifth transistor T5, and the first electrode of the light-emitting element ED is also accomplished through the first to eighth metal layers ML1, ML2, ML3, ML4, ML5, ML6, ML7, and ML8.

The first interlayer insulating layer INS1 may be located on the semiconductor backplane SBP. Each of the first vias VA1 may penetrate the first interlayer insulating layer INS1 to be connected to the contact terminal CTE exposed from the semiconductor backplane SBP. The first metal layers ML1 may be located on the first interlayer insulating layer INS1, and may be connected to the first via VA1.

The second interlayer insulating layer INS2 may be located on the first interlayer insulating layer INS1 and the first metal layers ML1. Each of the second vias VA2 may penetrate the second interlayer insulating layer INS2, and may be connected to the exposed first metal layer ML1. Each of the second metal layers ML2 may be located on the second interlayer insulating layer INS2, and may be connected to the second via VA2.

The third interlayer insulating layer INS3 may be located on the second interlayer insulating layer INS2 and the second metal layers ML2. Each of the third vias VA3 may penetrate the third interlayer insulating layer INS3, and may be connected to the exposed second metal layer ML2. Each of the third metal layers ML3 may be located on the third interlayer insulating layer INS3, and may be connected to the third via VA3.

A fourth interlayer insulating layer INS4 may be located on the third interlayer insulating layer INS3 and the third metal layers ML3. Each of the fourth vias VA4 may penetrate the fourth interlayer insulating layer INS4, and may be connected to the exposed third metal layer ML3. Each of fourth metal layers ML4 may be located on the fourth interlayer insulating layer INS4, and may be connected to the fourth via VA4.

A fifth interlayer insulating layer INS5 may be located on the fourth interlayer insulating layer INS4 and the fourth metal layers ML4. Each of the fifth vias VA5 may penetrate the fifth interlayer insulating layer INS5, and may be connected to the exposed fourth metal layer ML4. Each of fifth metal layers ML5 may be located on the fifth interlayer insulating layer INS5, and may be connected to the fifth via VA5.

A sixth interlayer insulating layer INS6 may be located on the fifth interlayer insulating layer INS5 and the fifth metal layers ML5. Each of the sixth vias VA6 may penetrate the sixth interlayer insulating layer INS6, and may be connected to the exposed fifth metal layer ML5. Each of sixth metal layers ML6 may be located on the sixth interlayer insulating layer INS6 and may be connected to the sixth via VA6.

A seventh interlayer insulating layer INS7 may be located on the sixth interlayer insulating layer INS6 and the sixth metal layers ML6. Each of the seventh vias VA7 may penetrate the seventh interlayer insulating layer INS7, and may be connected to the exposed sixth metal layer ML6. Each of seventh metal layers ML7 may be located on the seventh interlayer insulating layer INS7, and may be connected to the seventh via VA7.

An eighth interlayer insulating layer INS8 may be located on the seventh interlayer insulating layer INS7 and the seventh metal layers ML7. Each of the eighth vias VA8 may penetrate the eighth interlayer insulating layer INS8, and may be connected to the exposed seventh metal layer ML7. Each of eighth metal layers ML8 may be located on the eighth interlayer insulating layer INS8, and may be connected to the eighth via VA8.

The first to eighth metal layers ML1, ML2, ML3, ML4, ML5, ML6, ML7, and ML8 and the first to eighth vias VA1, VA2, VA3, VA4, VA5, VA6, VA7, and VA8 may be formed of substantially the same material. The first to eighth metal layers ML1, ML2, ML3, ML4, ML5, ML6, ML7, and ML8 and the first to eighth vias VA1, VA2, VA3, VA4, VA5, VA6, VA7, and VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1, VA2, VA3, VA4, VA5, VA6, VA7, and VA8 may be made of substantially the same material. First to eighth interlayer insulating layers INS1, INS2, INS3, INS4, INS5, INS6, INS7, and INS8 may be formed of a silicon oxide (SiOx)-based inorganic layer, but the present specification is not limited thereto.

The thicknesses of the first metal layer ML1, the second metal layer ML2, the third metal layer ML3, the fourth metal layer ML4, the fifth metal layer ML5, and the sixth metal layer ML6 may be larger than the thicknesses of the first via VA1, the second via VA2, the third via VA3, the fourth via VA4, the fifth via VA5, and the sixth via VA6, respectively. The thickness of each of the second metal layer ML2, the third metal layer ML3, the fourth metal layer ML4, the fifth metal layer ML5, and the sixth metal layer ML6 may be larger than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be about 1360 Å, the thickness of each of the second metal layer ML2, the third metal layer ML3, the fourth metal layer ML4, the fifth metal layer ML5, and the sixth metal layer ML6 may be about 1440 Å, and the thickness of each of the first via VA1, the second via VA2, the third via VA3, the fourth via VA4, the fifth via VA5, and the sixth via VA6 may be about 1150 Å.

The thickness of each of the seventh metal layer ML7 and the eighth metal layer ML8 may be larger than the thickness of the first metal layer ML1, the thickness of the second metal layer ML2, the thickness of the third metal layer ML3, the thickness of the fourth metal layer ML4, the thickness of the fifth metal layer ML5, and the sixth metal layer ML6. The thickness of the seventh metal layer ML7 and the thickness of the eighth metal layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, the thickness of each of the seventh metal layer ML7 and the eighth metal layer ML8 may be about 9000 Å. The thickness of each of the seventh via VA7 and the eighth via VA8 may be about 6000 Å.

A ninth interlayer insulating layer INS9 may be located on the eighth interlayer insulating layer INS8 and the eighth metal layers ML8. The ninth insulating layer INS9 may be formed of a silicon oxide (SiOx)-based inorganic layer, but the present specification is not limited thereto.

Each of the ninth vias VA9 may penetrate the ninth interlayer insulating layer INS9 and may be connected to the exposed eighth metal layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be about 16500 Å.

Each of the first reflective electrodes RL1 may be located on the ninth interlayer insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

Each of the second reflective electrodes RL2 may be located on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may be made of titanium nitride (TiN).

The step layer STPL may be located on the second reflective electrode RL2 overlapping the first pixel PX1. The step layer STPL may not be located in each of the second pixel PX2 and the third pixel PX3. To suitably reflect the light of the first color emitted from a first light-emitting layer EML1 of the first pixel PX1, the thickness of the step layer STPL may be set in consideration of the wavelength of the light of the first color and the distance from the first light-emitting layer EML1 to the fourth reflective electrode RL4. The step layer STPL may be formed of silicon carbonitride (SiCN) or a silicon oxide (SiOx)-based inorganic layer, but the present specification is not limited thereto. The thickness of the step layer STPL may be about 400 Å.

In the first pixel PX1, the third reflective electrode RL3 may be located on the second reflective electrode RL2 and the step layer STPL. In the second pixel PX2 and the third pixel PX3, the third reflective electrode RL3 may be located on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

At least one of the first reflective electrode RL1, the second reflective electrode RL2, or the third reflective electrode RL3 may be omitted in one or more embodiments.

The fourth reflective electrodes RL4 may be respectively located on the third reflective electrodes RL3. The fourth reflective electrodes RL4 may reflect light from the first to third intermediate layers EML1, EML2, and EML3. The fourth reflective electrodes RL4 may include a metal having high reflectivity to suitably reflect the light. The fourth reflective electrodes RL4 may be formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of the APC alloy and ITO, but the present specification is not limited thereto. Each of the fourth reflective electrodes RL4 may have a thickness of about 850 Å.

A tenth interlayer insulating layer INS10 may be located on the ninth interlayer insulating layer INS9 and the fourth reflective electrodes RL4. The tenth insulating layer INS10 may be formed of a silicon oxide (SiOx)-based inorganic layer, but the present specification is not limited thereto.

Each of the tenth vias VA10 may penetrate the tenth interlayer insulating layer INS10, and may be connected to an exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. Due to the presence of the step layer STPL, the thickness of the tenth via VA10 in the first pixel PX1 may be less than the thickness of the tenth via VA10 in each of the second pixel PX2 and the third pixel PX3. For example, the thickness of the tenth via VA10 in the first pixel PX1 may be about 800 Å, and the thickness of the tenth via VA10 in each of the second pixel PX2 and the third pixel PX3 may be about 1200 Å.

The light-emitting element layer EMTL may be located on the light-emitting element backplane EBP. The light-emitting element layer EMTL may include the light-emitting elements LE each having the first electrode AND, the intermediate layer IL, and the second electrode CAT, a pixel-defining layer PDL, and a plurality of trenches TRC.

The first electrode AND of each of the light-emitting elements ED may be located on the tenth interlayer insulating layer INS10, and may be connected to the tenth via VA10. The first electrode AND of each of the light-emitting elements ED may be connected to the drain region DA or the source region SA of the pixel transistor TRS through the tenth via VA10, the first to fourth reflective electrodes RL1, RL2, RL3, and RL4, the first to ninth vias VA1, VA2, VA3, VA4, VA5, VA6, VA7, VA8, and VA9, the first to eighth metal layers ML1, ML2, ML3, ML4, ML5, ML6, ML7, and ML8, and the contact terminal CTE. The first electrode AND of each of the light-emitting elements ED may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements ED may be titanium nitride (TiN).

The pixel-defining layer PDL may be located on a part of the first electrode AND of each of the light-emitting elements ED. The pixel-defining layer PDL may cover the edge of the first electrode AND of each of the light-emitting elements ED. The pixel-defining layer PDL may serve to partition the first emission areas EA1, the second emission areas EA2, and the third emission areas EA3.

The first emission area EA1 may be defined as an area in which the first electrode AND, the intermediate layer IL, and the second electrode CAT are sequentially stacked in the first pixel PX1 to emit light. The second emission area EA2 may be defined as an area in which the first electrode AND, the intermediate layer IL, and the second electrode CAT are sequentially stacked in the second pixel PX2 to emit light. The third emission area EA3 may be defined as an area in which the first electrode AND, the intermediate layer IL, and the second electrode CAT are sequentially stacked in the third pixel PX3 to emit light.

The pixel-defining layer PDL may include first to third pixel-defining layers PDL1, PDL2, and PDL3. The first pixel-defining layer PDL1 may be located on the edge of the first electrode AND of each of the light-emitting elements ED, the second pixel-defining layer PDL2 may be located on the first pixel-defining layer PDL1, and the third pixel-defining layer PDL3 may be located on the second pixel-defining layer PDL2. The first pixel-defining layer PDL1, the second pixel-defining layer PDL2, and the third pixel-defining layer PDL3 may be formed of a silicon oxide (SiOx)-based inorganic layer, but the present specification is not limited thereto. The first pixel-defining layer PDL1, the second pixel-defining layer PDL2, and the third pixel-defining layer PDL3 may each have a thickness of about 500 Å.

Each of the plurality of trenches TRC may penetrate the first pixel-defining layer PDL1, the second pixel-defining layer PDL2, and the third pixel-defining layer PDL3. The tenth interlayer insulating layer INS10 may be partially recessed at each of the plurality of trenches TRC.

At least one trench TRC may be located between adjacent pixels PX1, PX2, and PX3. Although FIG. 6 illustrates that two trenches TRC are located between adjacent pixels PX1, PX2, and PX3, the present specification is not limited thereto.

The intermediate layer IL may include a first intermediate layer IL1, a second intermediate layer IL2, and a third intermediate layer IL3.

The intermediate layer IL may have a tandem structure including the plurality of intermediate layers IL1, IL2, and IL3 that respectively emit different lights. For example, the intermediate layer IL may include the first intermediate layer IL1 that emits light of the first color, the second intermediate layer IL2 that emits light of the third color, and the third intermediate layer IL3 that emits light of the second color. The first intermediate layer IL1, the second intermediate layer IL2, and the third intermediate layer IL3 may be sequentially stacked.

The first intermediate layer IL1 may have a structure in which a first hole transport layer, a first organic light-emitting layer that emits light of the first color, and a first electron transport layer are sequentially stacked. The second intermediate layer IL2 may have a structure in which a second hole transport layer, a second organic light-emitting layer that emits light of the third color, and a second electron transport layer are sequentially stacked. The third intermediate layer IL3 may have a structure in which a third hole transport layer, a third organic light-emitting layer that emits light of the second color, and a third electron transport layer are sequentially stacked.

A first charge generation layer for supplying charges to the second intermediate layer IL2 and for supplying electrons to the first intermediate layer IL1 may be located between the first intermediate layer IL1 and the second intermediate layer IL2. A second charge generation layer for supplying charges to the third intermediate layer IL3 and for supplying electrons to the second intermediate layer IL2 may be located between the second intermediate layer IL2 and the third intermediate layer IL3.

The first intermediate layer IL1 may be located on the first electrodes AND and the pixel-defining layer PDL, and may be located on the bottom surface of each trench TRC. Due to the trench TRC, the first intermediate layer IL1 may be separated between adjacent pixels PX1, PX2, and PX3. The second intermediate layer IL2 may be located on the first intermediate layer IL1. Due to the trench TRC, the second intermediate layer IL2 may be separated between adjacent pixels PX1, PX2, and PX3. The third intermediate layer IL3 may be located on the second intermediate layer IL2. Due to the trench TRC, the third intermediate layer IL3 may be separated between adjacent pixels PX1, PX2, and PX3. That is, each of the plurality of trenches TRC may be a structure for separating the first to third intermediate layers IL1, IL2, and IL3 of the light-emitting element layer EMTL between adjacent pixels PX1, PX2, and PX3.

To stably separate the first to third intermediate layers IL1, IL2, and IL3 of the light-emitting element layer EMTL between adjacent pixels PX1, PX2, and PX3, the height of each of the plurality of trenches TRC may be greater than the height of the pixel-defining layer PDL. The height of each of the plurality of trenches TRC refers to the length of each of the plurality of trenches TRC in the third direction DR3. The height of the pixel-defining layer PDL refers to the length of the pixel-defining layer PDL in the third direction DR3.

To cut off the first to third intermediate layers IL1, IL2, and IL3 of the light-emitting element layer EMTL between the neighboring pixels PX1, PX2, and PX3, another structure may exist instead of the trench TRC. For example, instead of the trench TRC, a reverse tapered partition wall may be located on the pixel-defining layer PDL.

The number of the intermediate layers IL1, IL2, and IL3 that emit different lights is not limited to that shown in FIG. 6. For example, the intermediate layer IL may include two intermediate layers. In this case, one of the two intermediate layers may be substantially the same as the first intermediate layer IL1, and the other may include a second hole transport layer, a second organic light-emitting layer, a third organic light-emitting layer, and a second electron transport layer. In this case, a charge generation layer for supplying electrons to one intermediate layer and for supplying charges to another intermediate layer may be located between the two intermediate layers.

In addition, FIG. 6 illustrates that the first to third intermediate layers IL1, IL2, and IL3 are all located in each of the first emission area EA1, the second emission area EA2, and the third emission area EA3, but the present specification is not limited thereto. For example, the first intermediate layer IL1 may be located in the first emission area EA1, while not being located in the second emission area EA2 and the third emission area EA3. Furthermore, the second intermediate layer IL2 may be located in the second emission area EA2, while not being located in the first emission area EA1 and the third emission area EA3. Further, the third intermediate layer IL3 may be located in the third emission area EA3, while not being located in the first emission area EA1 and the second emission area EA2. In this case, first to third color filters CF1, CF2, and CF3 of the optical layer OPL may be omitted.

The second electrode CAT may be located on the third intermediate layer IL3. The second electrode CAT may be located on the third intermediate layer IL3 in each of the plurality of trenches TRC. The second electrode CAT may be formed of a transparent conductive material (TCO), such as ITO or IZO that can transmit light, or may be formed of a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be located on the light-emitting element layer EMTL. The encapsulation layer TFE may include at least one inorganic layer TFE1 and TFE2 to reduce or prevent the likelihood of oxygen or moisture permeating into the light-emitting element layer EMTL. In addition, the encapsulation layer ENC may include at least one organic layer to protect the light-emitting element layer EMTL from foreign substances, such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be located on the second electrode CAT, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed of multiple layers in which one or more inorganic layers of silicon nitride (SiNₓ), silicon oxynitride (SiON), silicon oxide (SiOₓ), titanium oxide (TiOₓ), or aluminum oxide (AlOₓ) layers are alternately stacked. The encapsulation organic layer TFE2 may be a monomer. Alternatively, the encapsulation organic layer TFE2 may be an organic layer, such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member, such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first pixel PX1. The first color filter CF1 may transmit light of the first color (e.g., light of a blue wavelength band). The blue wavelength band may be about 370 nm to about 460 nm. Thus, the first color filter CF1 may transmit light of the first color among light emitted from the first emission area EA1.

The second color filter CF2 may overlap the second emission area EA2 of the second pixel PX2. The second color filter CF2 may transmit light of the second color (e.g., light of a green wavelength band). The green wavelength band may be approximately about nm to about 560 nm. Thus, the second color filter CF2 may transmit light of the second color among light emitted from the second emission area EA2.

The third color filter CF3 may overlap the third emission area EA3 of the third pixel PX3. The third color filter CF3 may transmit light of the third color (e.g., light of a red wavelength band). The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) such that light travels in the third direction DR3 at an interface between the filling layer FIL and the plurality of lenses LNS. Further, the filling layer FIL may be a planarization layer. The filling layer FIL may be an organic layer, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but the present specification is not limited thereto. However, when visibility degradation caused by reflection of external light is sufficiently overcome by the first to third color filters CF1, CF2, and CF3, the polarizing plate may be omitted.

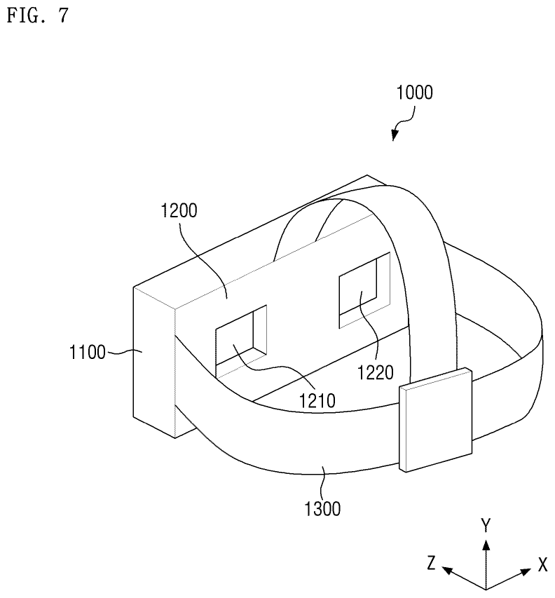

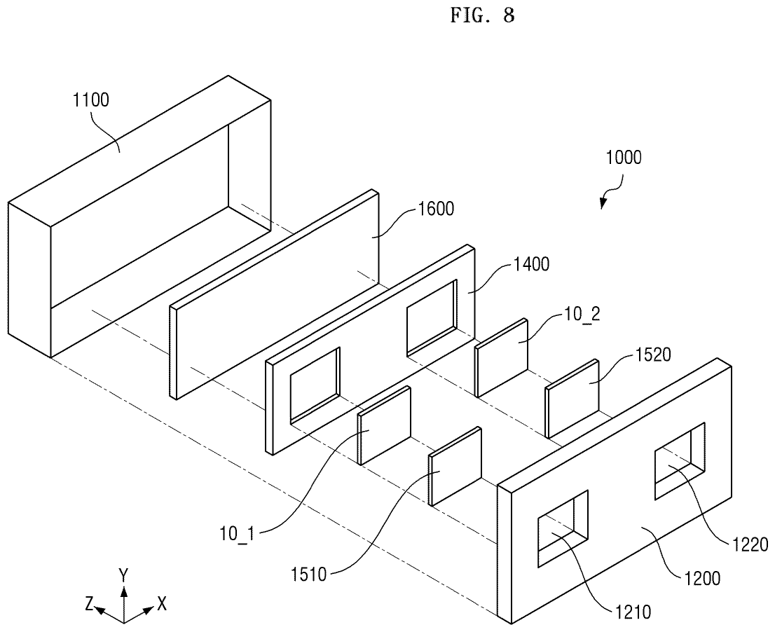

FIG. 7 is a perspective view illustrating a head mounted display device according to one or more embodiments. FIG. 8 is an exploded perspective view illustrating an example of the head mounted display device of FIG. 7.

Referring to FIGS. 7 and 8, a head mounted display device 1000 according to one or more embodiments includes a first display device 10_1, a second display device 10_2, a display device housing 1100, a display device housing 1200, a first eyepiece 1210, a second eyepiece 1220, a head mounted band 1300, a middle frame 1400, a first optical member 1510, a second optical member 1520, a control circuit board 1600, and a connector 1610.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 to 6, a repeated description corresponding to the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600, and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector 1610. The control circuit board 1600 may convert an image source inputted from the outside into the digital video data DATA, and may transmit the digital video data DATA to the first display device 10_1 and the second display device 10_2 through the connector 1610.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, the control circuit board 1600, and the connector 1610. The display device housing 1200 covers one open surface of the display device housing 1100. The display device housing 1200 may include the first eyepiece 1210 at which the user's left eye is located, and the second eyepiece 1220 at which the user's right eye is located. FIGS. 7 and 8 illustrate that the first eyepiece 1210 and the second eyepiece 1220 are located separately, but the present specification is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Accordingly, the user may view the image of the first display device 10_1 magnified as a virtual image by the first optical member 1510 through the first eyepiece 1210, and may view the image of the second display device 10_2 magnified as a virtual image by the second optical member 1520 through the second eyepiece 1220.

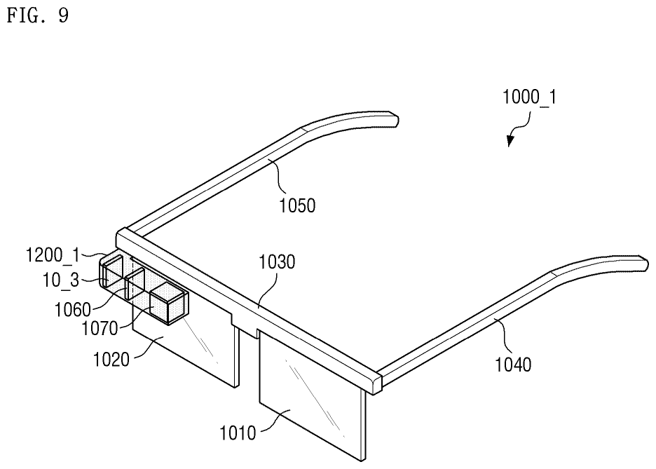

The head mounted band 1300 serves to secure the display device housing 1100 to the user's head, such that the first eyepiece 1210 and the second eyepiece 1220 of the display device housing 1200 remain located on the user's left and right eyes, respectively. When the display device housing 1200 is implemented to be lightweight and compact, the head mounted display device 1000 may be provided with, as shown in FIG. 9, an eyeglass frame instead of a head mounted band 800.

In addition, the head mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 9 is a perspective view illustrating a head mounted display device according to one or more embodiments.

Referring to FIG. 9, a head mounted display device 1000_1 according to one or more embodiments may be an eyeglasses-type display device in which a display device housing 1200_1 is implemented in a lightweight and compact manner. The head mounted display device 1000_1 according to one or more embodiments may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. An image displayed on the display device 10_3 may be magnified by the optical member 1060, and the optical path may be converted by the optical path conversion member 1070 to provide the image to the user's right eye through the right eye lens 1020. As a result, the user may view an augmented reality image, through the right eye, in which a virtual image displayed on the display device 10_3 and a real image seen through the right eye lens 1020 are combined.

FIG. 9 illustrates that the display device housing 1200_1 is located at the end on the right side of the support frame 1030, but the present specification is not limited thereto. For example, the display device housing 1200_1 may be located on the left end of the support frame 1030, and in this case, the image of the display device 10_3 may be provided to the user's left eye. Alternatively, the display device housing 1200_1 may be located on both the left and right ends of the support frame 1030, and in this case, the user may view the image displayed on the display device 10_3 through both the left and right eyes.

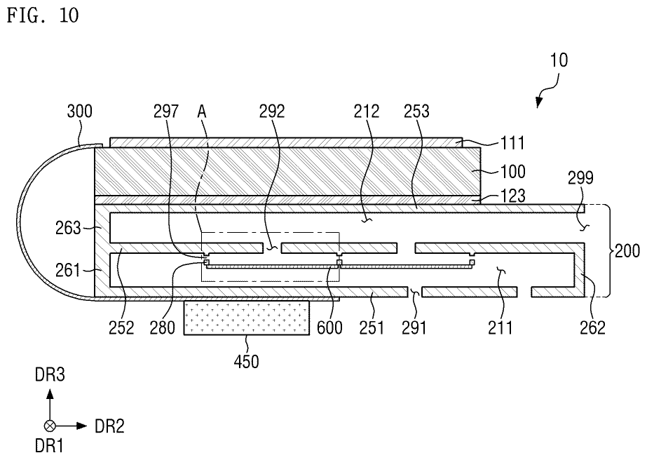

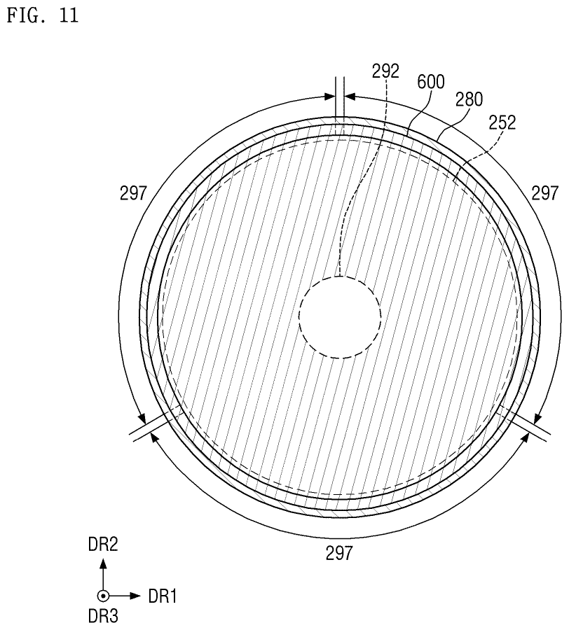

FIG. 10 is a cross-sectional view of the display device 10 according to one or more embodiments, and FIG. 11 is a plan view of a piezoelectric element 600, a support 280 and a through hole of part A of FIG. 10.

As shown in FIG. 10, the display device 10 according to one or more embodiments may include the driving circuit 450, the heat dissipation layer 200, the display panel 100, a polarizing plate 111, the circuit board 300, and a heat conduction layer 123 (or a thermal interface material).

For the description of the driving circuit 450, the display panel 100, and the circuit board 300 of FIG. 10, refer to the description of the driving circuit 450, the display panel 100, and the circuit board 300 of FIG. 1. Meanwhile, the polarizing plate 111 may be located on the display panel 100. For the description of this polarizing plate 111, refer to the description of the polarizing plate related to FIG. 6 described above.

The heat dissipation layer 200 may discharge the heat generated from a heating element (e.g., at least one of the driving circuit 450 or the display panel 100) to the outside to dissipate the heat of the display device 10. At least a part of the heat dissipation layer 200 may include, for example, a plastic material or a metal material. In addition, at least a part of the heat dissipation layer 200 may include a plastic material and a metal material together.

The heat dissipation layer 200 may include a lower plate 251, an intermediate plate 252, an upper plate 253, a first side plate 261, a second side plate 262, a third side plate 263, the support 280, a first chamber 211, a second chamber 212, and the piezoelectric element 600. Here, the aforementioned chambers 211 and 212 or the spaces of the chambers 211 and 212 may be defined by the lower plate 251, the intermediate plate 252, the upper plate 253, the first side plate 261, the second side plate 262, and the third side plate 263.

The lower plate 251, the intermediate plate 252, the upper plate 253, the first side plate 261, the second side plate 262, the third side plate 263, and the support 280 may be integrally formed.

The lower plate 251 may be located on the driving circuit 450. For example, the lower plate 251 may be located on the driving circuit 450 in the third direction DR3 to overlap the driving circuit 450. The lower plate 251 may have a rectangular shape extending along the first direction DR1. The lower plate 251 may have at least one through hole 291 penetrating in a direction (e.g., the third direction DR3) perpendicular to the extension direction of the lower plate 251. The lower plate 251 may be in contact with the circuit board 300.

The intermediate plate 252 may be located on the lower plate 251. For example, the intermediate plate 252 may be located on the lower plate 251 in the third direction DR3 to overlap the lower plate 251. In this case, the intermediate plate 252 may be located between the lower plate 251 and the upper plate 253. The intermediate plate 252 may overlap the lower plate 251 and the upper plate 253. The intermediate plate 252 may have a rectangular shape extending along the first direction DR1. The intermediate plate 252 may have at least one through hole 292 penetrating in a direction (e.g., the third direction DR3) perpendicular to the extension direction of the intermediate plate 252.

The upper plate 253 may be located on the intermediate plate 252. For example, the upper plate 253 may be located on the intermediate plate 252 in the third direction DR3 to overlap the intermediate plate 252. The upper plate 253 may have a rectangular shape extending in the first direction DR1. The upper plate 253 may be in contact with the heat conduction layer 123.

The first side plate 261 may be located at one edge of the lower plate 251. The first side plate 261 may have a rectangular shape extending in the third direction DR3 from one edge of the lower plate 251. The first side plate 261 may be located between one edge of the lower plate 251 and one edge of the intermediate plate 252, for example. The first side plate 261 may be connected to one edge of the lower plate 251 and one edge of the intermediate plate 252.

The second side plate 262 may be located at the other edge of the lower plate 251. The second side plate 262 may have a rectangular shape extending in the third direction DR3 from the other edge of the lower plate 251. The second side plate 262 may be located between the other edge of the lower plate 251 and the other edge of the intermediate plate 252, for example. The second side plate 262 may be connected to the other edge of the lower plate 251 and the other edge of the intermediate plate 252. The second side plate 262 may face, or may be opposite to, the first side plate 261 described above.

The third side plate 263 may be located at one edge of the intermediate plate 252. The third side plate 263 may have a rectangular shape extending in the third direction DR3 from one edge of the intermediate plate 252. The third side plate 263 may be located between one edge of the intermediate plate 252 and one edge of the upper plate 253, for example. The third side plate 263 may be connected to one edge of the intermediate plate 252 and one edge of the upper plate 253.

The heat dissipation layer 200 may have an opening 299 between the other edge of the intermediate plate 252 described above and the other edge of the upper plate 253. In other words, the opening 299 may be located between the other edge of the intermediate plate 252 and the other edge of the upper plate 253. The opening 299 may face, or may be opposite to, the third side plate 263 described above.

The first chamber 211 may be located between the lower plate 251 and the intermediate plate 252 described above. For example, the first chamber 211 may be a region defined by being surrounded by the lower plate 251, the intermediate plate 252, the first side plate 261, and the second side plate 262 in a rectangular shape. In addition, the first chamber 211 may be a structure including all of the lower plate 251, the intermediate plate 252, the first side plate 261, and the second side plate 262 described above, and the space surrounded by them.

The second chamber 212 may be located between the intermediate plate 252 and the upper plate 253 described above. For example, the second chamber 212 may be a region defined by being surrounded by the intermediate plate 252, the upper plate 253, and the third side plate 263 in a U-shape. In addition, the second chamber 212 may be a structure including all of the intermediate plate 252, the upper plate 253, and the third side plate 263 described above, and the space surrounded by them. The second chamber 212 may have the opening 299 on one side thereof. The second chamber 212 may have the opening 299 between the other edge of the intermediate plate 252 and the other edge of the upper plate 253. In other words, the opening 299 may be located between the other edge of the intermediate plate 252 and the other edge of the upper plate 253.

The support 280 may be located in at least one of the chambers. For example, the support 280 may be located in the first chamber 211 between the lower plate 251 and the intermediate plate 252. When the support 280 is located in the first chamber 211, the support 280 may extend from the bottom surface of the intermediate plate 252 in a reverse direction to the third direction DR3 (hereinafter, referred to as a third reverse direction). The support 280 may have a through hole 297 penetrating in a direction (e.g., the first direction DR1 and/or the second direction DR2) perpendicular to the extension direction of the support 280.

The piezoelectric element 600 may be located in at least one of the chambers. For example, as illustrated in FIG. 10, the piezoelectric element 600 may be located in the first chamber 211. The piezoelectric element 600 may be located between the support 280 and the lower plate 251 in the first chamber 211. The piezoelectric element 600 may be supported by the support 280. For example, the piezoelectric element 600 may be located on the support 280. The edge of the piezoelectric element 600 may be located on the support 280. The piezoelectric element 600 may be attached to the support 280. In one or more embodiments, the piezoelectric element 600 may be fixed on the support 280 by the support 280 and by other fixing means coupled to the support 280.

The piezoelectric element 600 may be transformed according to a voltage from the outside. For example, depending on the direction of the current flowing through the piezoelectric element 600, the piezoelectric element 600 may be transformed to be convex in the third direction DR3 or in the third reverse direction. For example, depending on the direction of the current, the piezoelectric element 600 may be transformed to form a parabolic shape that is convex in the third direction DR3, or to form a parabolic shape that is convex in the third reverse direction. Here, the third direction DR3 or the third reverse direction is the direction in which the driving circuit 450, the heat dissipation layer 200, and the display panel 100 described above are stacked, and the piezoelectric element 600 may be transformed in the third direction DR3 or in the third reverse direction. At least one piezoelectric element 600 may be provided in at least one of the chambers. FIG. 10 illustrates an example in which two piezoelectric elements 600 are located in the first chamber 211.

As illustrated in FIGS. 10 and 11, the piezoelectric element 600 may overlap at least one through hole 292. For example, the piezoelectric element 600 may be located on the support 280 to overlap the through hole(s) 292 of the intermediate plate 252. Here, in plan view, the through hole(s) 292 of the intermediate plate 252 may be surrounded by the support 280, as illustrated in FIG. 11.

As shown in FIG. 11, the piezoelectric element 600, the support 280, and the through hole(s) 292 of the intermediate plate 252 may have a circular shape.

In one or more embodiments, the piezoelectric element 600 may be, by way of non-limiting example, a piezo pump or a piezo micro pump.

As shown in FIG. 11, the through hole 297 of the support 280 may be formed along the arcs of three sectors of the support 280 having the circular shape. FIG. 11 illustrates an example in which the support 280 has three through holes 297 separated from each other. Here, as shown in FIG. 11, each through hole 297 may have a length (e.g., an arc length) corresponding to the central angle (e.g., about 120 degrees) of each sector.

The heat conduction layer 123 may be located between the heat dissipation layer 200 and the display panel 100. For example, the heat conduction layer 123 may be located between the upper plate 253 of the heat dissipation layer 200 and the bottom surface of the display panel 100. The heat conduction layer 123 may improve the thermal conductivity between the display panel 100 and the heat dissipation layer 200. In one or more embodiments, the heat conduction layer 123 may contain an adhesive material, in which case the display panel 100 and the heat dissipation layer 200 may be bonded to each other by the heat conduction layer 123.

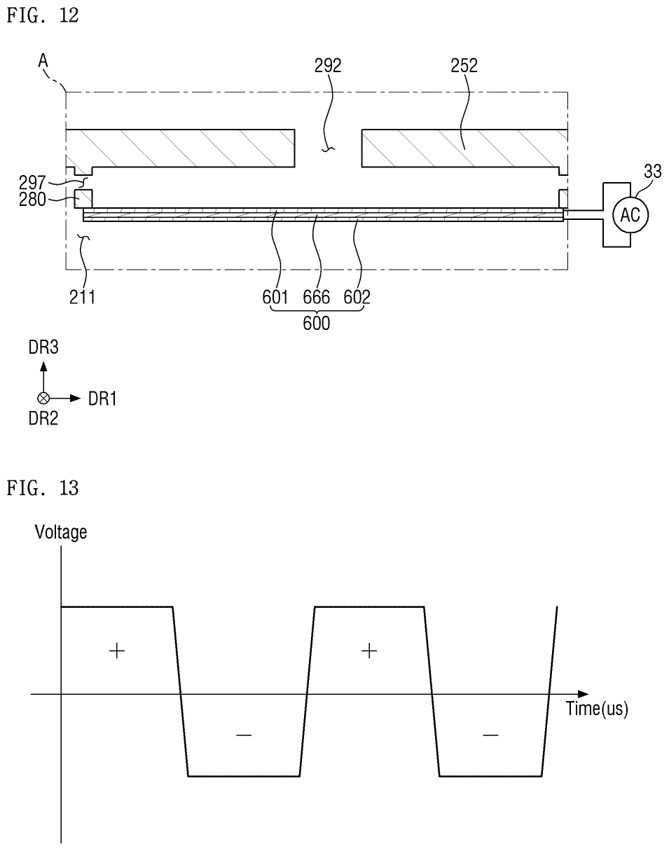

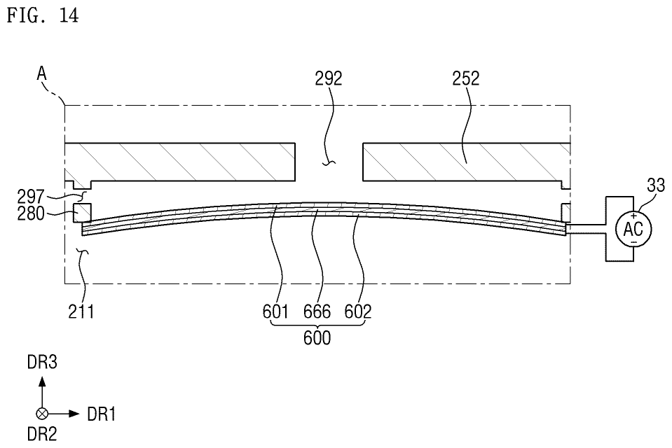

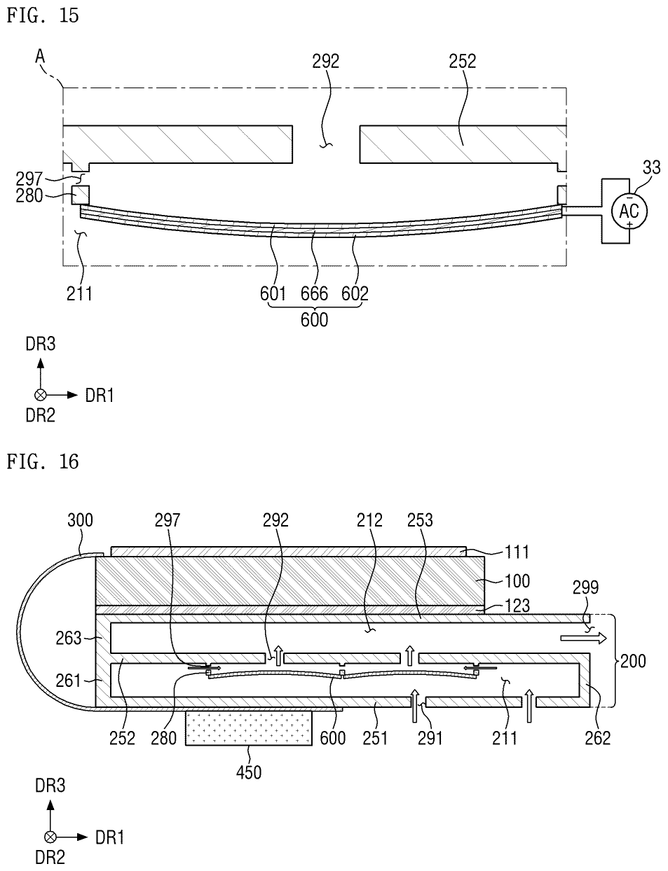

FIG. 12 is an enlarged cross-sectional view of part A of FIG. 11, FIG. 13 is a timing diagram of an AC power supplied to the piezoelectric element 600 of FIG. 12, and FIGS. 14 and 15 are diagrams for explaining the operation of the piezoelectric element 600 of FIG. 12.

As shown in FIG. 12, the piezoelectric element 600 may include a first conductive layer 601, a second conductive layer 602, and a piezoelectric layer 666.

The first conductive layer 601 may be located on the support 280. The first conductive layer 601 may be a conductive layer for applying a first voltage to the piezoelectric layer 666.

The second conductive layer 602 may be located on the first conductive layer 601. The second conductive layer 602 may be a conductive layer for applying a second voltage to the piezoelectric layer 666.

The first conductive layer 601 and the second conductive layer 602 may be applied with voltages of opposite polarities from an AC voltage source. For example, as illustrated in FIG. 13, the first voltage applied to the first conductive layer 601 may be an AC voltage having a positive polarity and a negative polarity alternately over time. Meanwhile, the second voltage applied to the second conductive layer 602 may be an AC voltage having a polarity that is opposite to that of the first voltage at the same timing. For example, the second voltage may be an AC voltage that is phase-inverted by 180 degrees with respect to the first voltage of FIG. 13.

The piezoelectric layer 666 may be located between the first conductive layer 601 and the second conductive layer 602.

As shown in FIG. 14, when the first voltage of the positive polarity (+) is applied to the first conductive layer 601 and the second voltage of the negative polarity (−) is applied to the second conductive layer 602, a first current flowing in the third reverse direction may be generated in the piezoelectric layer 666. As a result, as illustrated in FIG. 14, the piezoelectric element 600 may be transformed by the first current to have a parabolic shape that is convex in the third direction DR3.

Meanwhile, as shown in FIG. 15, when the first voltage of the negative polarity (−) is applied to the first conductive layer 601 and the second voltage of the positive polarity (+) is applied to the second conductive layer 602, a second current flowing in the third direction DR3 may be generated in the piezoelectric layer 666. As a result, as illustrated in FIG. 15, the piezoelectric element 600 may be transformed by the second current to have a parabolic shape that is convex in the third reverse direction.

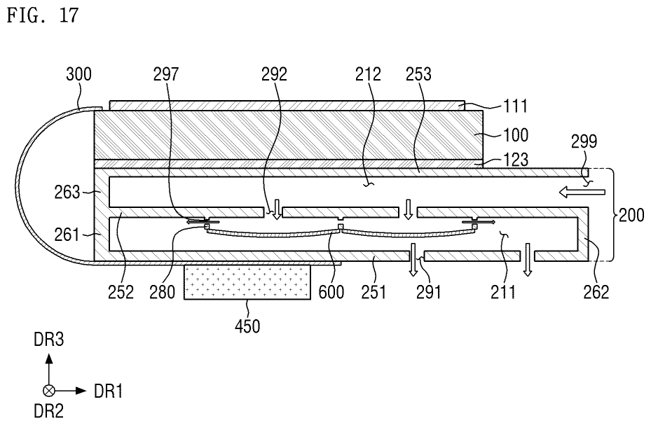

FIGS. 16 and 17 are diagrams for describing the operation of the display device 10 of FIG. 10.

First, as shown in FIG. 16, when the piezoelectric element 600 is transformed to have a parabolic shape that is convex in the third direction DR3, the pressure of the first chamber 211 becomes lower than the pressure outside the heat dissipation layer 200, so the air outside the heat dissipation layer 200 may be drawn into the first chamber 211 through the through hole(s) 291 of the lower plate 251. As a result, the pressure of the first chamber 211 may increase and may become higher than the pressure of the second chamber 212. Accordingly, the air of the first chamber 211 may be introduced into the second chamber 212 through the through hole(s) 292 of the intermediate plate 252. As a result, the pressure of the second chamber 212 may increase and may become higher than the pressure outside the heat dissipation layer 200. Accordingly, the air introduced into the second chamber 212 may be discharged to the outside through the opening 299. For example, the external air introduced into the heat dissipation layer 200 may sequentially pass through the through hole(s) 291 of the lower plate 251, the first chamber 211, the through hole(s) 292 of the intermediate plate 252, the second chamber 212, and the opening 299 along the directions indicated by the arrows shown in FIG. 16 to be discharged to the outside of the heat dissipation layer 200. In other words, the air outside the heat dissipation layer 200 may be introduced into the heat dissipation layer 200 through the through hole(s) 291 of the lower plate 251 and then discharged to the outside through the opening 299 of the heat dissipation layer 200. Accordingly, the hot air in the first chamber 211 and the second chamber 212 may be discharged to the outside. Therefore, the heat of the driving circuit 450 and the display panel 100 may be easily released to the outside, so that the heat may be effectively dissipated from the display device 10.

Meanwhile, as illustrated in FIG. 17, when the piezoelectric element 600 is transformed to have a parabolic shape that is convex in the third direction, the pressure of the second chamber 212 becomes lower than the pressure outside the heat dissipation layer 200, so the air outside the heat dissipation layer 200 may be introduced into the second chamber 212 through the opening 299. As a result, the pressure of the second chamber 212 may increase and may become higher than the pressure of the first chamber 211. Accordingly, the air of the second chamber 212 may be introduced into the first chamber 211 through the through hole(s) 292 of the intermediate plate 252. As a result, the pressure of the first chamber 211 may increase and may become higher than the pressure outside the heat dissipation layer 200. Accordingly, the air drawn into the first chamber 211 may be discharged to the outside of the heat dissipation layer 200 through the through hole(s) 291 of the lower plate 251. For example, the external air introduced into the heat dissipation layer 200 may sequentially pass through the opening 299 of the upper plate 253, the second chamber 212, the through hole(s) 292 of the intermediate plate 252, the first chamber 221, and the through hole(s) 291 of the first chamber 211 along the directions indicated by the arrows shown in FIG. 17 to be discharged to the outside of the heat dissipation layer 200. In other words, the air outside the heat dissipation layer 200 may be drawn into the heat dissipation layer 200 through the opening 299, and then may be discharged to the outside through the through hole(s) 291 of the lower plate 251. Accordingly, the hot air in the first chamber 211 and the second chamber 212 may be discharged to the outside. Therefore, the heat of the driving circuit 450 and the display panel 100 may be easily released to the outside, so that heat dissipation of the display device 10 may be effectively carried out.

In one or more embodiments, as illustrated in FIGS. 16 and 17, as the piezoelectric element 600 is alternately transformed along the third direction DR3 and the third reverse direction, air circulation occurs more actively in the heat dissipation layer 200, so that the heat dissipation of the display device 10 may be more effectively carried out.

In one or more embodiments, the frequency of the piezoelectric element 600 (e.g., the transformation cycle of the piezoelectric element 600 in the third direction DR3 and the third reverse direction) may be adjusted by adjusting the frequency of the AC voltage applied to the piezoelectric element 600.

According to the display device 10 of one or more embodiments, because the heat dissipation is performed through the piezoelectric element 600 of the heat dissipation layer 200, the components of the heat dissipation layer may be simplified, and the size of the heat dissipation layer 200 may be reduced. As a consequence, the size of the display device 10 may also be reduced.

In addition, according to the display device of one or more embodiments, because the heat dissipation is performed through the piezoelectric element 600, noise during the heat dissipation of the display device 10 may be reduced.

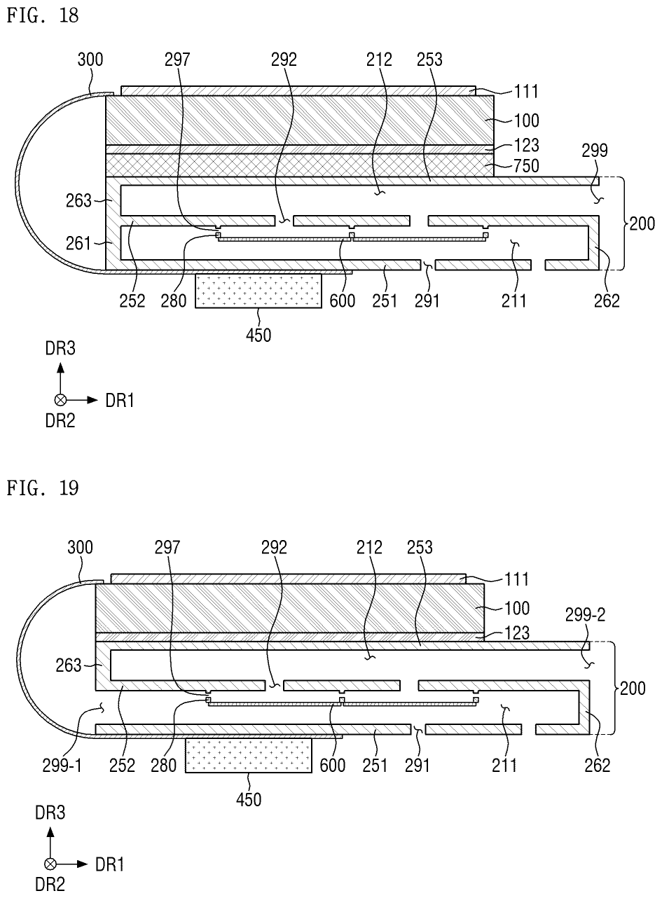

FIG. 18 is a cross-sectional view of the display device 10 according to one or more embodiments.

The display device 10 shown in FIG. 18 is different from the display device 10 of FIG. 10 in that it further includes a metal layer 750. The following description will mainly focus on this difference.

As shown in FIG. 18, the display device 10 according to one or more embodiments may further include the metal layer 750 located between the heat dissipation layer 200 and the heat conduction layer 123. For example, the metal layer 750 may be located between the upper plate 253 of the heat dissipation layer 200 and the heat conduction layer 123.

For example, the metal layer 750 may enable the heat of the display panel 100 to be better transferred to the heat dissipation layer 200.

In one or more embodiments, a vapor chamber may be used instead of the metal layer 750. In other words, the vapor chamber may be located between the upper plate 253 of the heat dissipation layer 200 and the heat conduction layer 123 instead of the metal layer 750.

FIG. 19 is a cross-sectional view of the display device 10 according to one or more embodiments.

The display device 10 shown in FIG. 19 is different from the display device 10 of FIG. 10 in the structure of the heat dissipation layer 200. The following description will mainly focus on this difference.

As shown in FIG. 19, the heat dissipation layer 200 may have a first opening 299-1 and a second opening 299-2.

The heat dissipation layer 200 (or the first chamber 211) may have the first opening 299-1 between one edge of the lower plate 251 and one edge of the intermediate plate 252. In other words, the first opening 299-1 may be located between one edge of the lower plate 251 and one edge of the intermediate plate 252.

The heat dissipation layer 200 (or the second chamber 212) may have a second opening 299-2 between the other edge of the intermediate plate 252 and the other edge of the upper plate 253. In other words, the second opening 299-2 may be located between the other edge of the intermediate plate 252 and the other edge of the upper plate 253. Here, the second opening 299-2 is the same as the above-described opening 299 of FIG. 11.

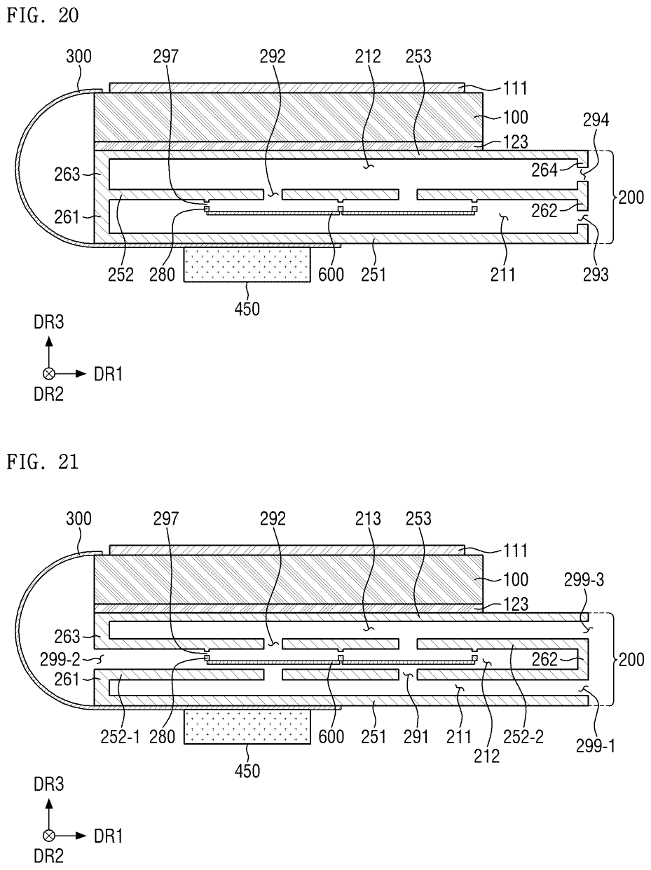

FIG. 20 is a cross-sectional view of the display device 10 according to one or more embodiments.

The display device 10 shown in FIG. 20 is different from the display device 10 of FIG. 10 in the structure of the heat dissipation layer 200. The following description will mainly focus on this difference.

As illustrated in FIG. 20, the second side plate 262 of the heat dissipation layer 200 may have a through hole 293 penetrating the second side plate 262 in a direction (e.g., the first direction DR1) perpendicular to the extension direction (e.g., the third direction DR3) thereof.

In addition, as illustrated in FIG. 20, the heat dissipation layer 200 may further include a fourth side plate 264.

The fourth side plate 264 may be located at the other edge of the intermediate plate 252. The fourth side plate 264 may have a rectangular shape extending in the third direction DR3 from the other side edge of the intermediate plate 252. The fourth side plate 264 may be located between the other edge of the intermediate plate 252 and the other edge of the upper plate 253, for example. The fourth side plate 264 may be connected to the other edge of the intermediate plate 252 and the other edge of the upper plate 253. The fourth side plate 264 may have a through hole 294 penetrating the fourth side plate 264 in a direction (e.g., the first direction DR1) perpendicular to the extension direction thereof. The fourth side plate 264 may face, or may be opposite to, the third side plate 263.

Meanwhile, in the display device 10 of FIG. 20, the lower plate 251 may not have a through hole.

FIG. 21 is a cross-sectional view of the display device 10 according to one or more embodiments.

The display device 10 shown in FIG. 21 is different from the display device 10 of FIG. 10 in the structure of the heat dissipation layer 200. The following description will mainly focus on this difference.

Referring to FIG. 21, the heat dissipation layer 200 may include the lower plate 251, a plurality of intermediate plates (e.g., a first intermediate plate 252-1 and a second intermediate plate 252-2), the upper plate 253, the first side plate 261, the second side plate 262, the third side plate 263, a plurality of chambers (e.g., the first chamber 211, the second chamber 212, and a third chamber 213), the support 280, and the piezoelectric element 600. Here, the above-described chambers 211, 212, and 213 or the spaces of these chambers 211, 212, and 213 may be defined by the lower plate 251, the plurality of intermediate plates 252-1 and 252-2, the upper plate 253, the first side plate 261, the second side plate 262, and the third side plate 263.

The lower plate 251, the first intermediate plate 252-1, the second intermediate plate 252-2, the upper plate 253, the first side plate 261, the second side plate 262, the third side plate 263, and the support 280 may be integrally formed.

The lower plate 251 may be located on the driving circuit 450. For example, the lower plate 251 may be located on the driving circuit 450 in the third direction DR3 to overlap the driving circuit 450. The lower plate 251 may have a rectangular shape extending along the first direction DR1. The lower plate 251 may be in contact with the circuit board 300.

The first intermediate plate 252-1 may be located on the lower plate 251. For example, the first intermediate plate 252-1 may be located on the lower plate 251 in the third direction DR3 to overlap the lower plate 251. In this case, the first intermediate plate 252-1 may be located between the lower plate 251 and the second intermediate plate 252-2. The first intermediate plate 252-1 may overlap the lower plate 251 and the second intermediate plate 252-2. The first intermediate plate 252-1 may have a rectangular shape extending along the first direction DR1. The first intermediate plate 252-1 may have at least one through hole 291 penetrating the first intermediate plate 252-1 in a direction (e.g., the third direction DR3) perpendicular to the extension direction thereof.

The second intermediate plate 252-2 may be located on the first intermediate plate 252-1. For example, the second intermediate plate 252-2 may be located on the first intermediate plate 252-1 in the third direction DR3 to overlap the first intermediate plate 252-1. In this case, the second intermediate plate 252-2 may be located between the first intermediate plate 252-1 and the upper plate 253. The second intermediate plate 252-2 may overlap the first intermediate plate 252-1 and the upper plate 253. The second intermediate plate 252-2 may have a rectangular shape extending along the first direction DR1. The second intermediate plate 252-2 may have at least one through hole 292 penetrating in a direction (e.g., the third direction DR3) perpendicular to the extension direction the second intermediate plate 252-2.

The upper plate 253 may be located on the second intermediate plate 252-2. For example, the upper plate 253 may be located on the second intermediate plate 252-2 in the third direction DR3 to overlap the second intermediate plate 252-2. The upper plate 253 may have a rectangular shape extending in the first direction DR1. The upper plate 253 may be in contact with the heat conduction layer 123.

The first side plate 261 may be located at one edge of the lower plate 251. The first side plate 261 may have a rectangular shape extending in the third direction DR3 from one edge of the lower plate 251. The first side plate 261 may be located between one edge of the lower plate 251 and one edge of the first intermediate plate 252-1. The first side plate 261 may be connected to one edge of the lower plate 251 and one edge of the first intermediate plate 252-1.

The second side plate 262 may be located at the other edge of the first intermediate plate 252-1. The second side plate 262 may have a rectangular shape extending in the third direction DR3 from the other edge of the first intermediate plate 252-1. The second side plate 262 may be located between the other edge of the first intermediate plate 252-1 and the other edge of the second intermediate plate 252-2, for example. The second side plate 262 may be connected to the other edge of the first intermediate plate 252-1 and the other edge of the second intermediate plate 252-2.

The third side plate 263 may be located at one edge of the second intermediate plate 252-2. The third side plate 263 may have a rectangular shape extending in the third direction DR3 from one edge of the second intermediate plate 252-2. The third side plate 263 may be located between one edge of the second intermediate plate 252-2 and one edge of the upper plate 253, for example. The third side plate 263 may be connected to one edge of the second intermediate plate 252-2 and one edge of the upper plate 253.

The heat dissipation layer 200 may have a first opening 299-1 between the other edge of the lower plate 251 and the other edge of the first intermediate plate 252-1 described above. In other words, the first opening 299-1 may be located between the other edge of the lower plate 251 and the other edge of the first intermediate plate 252-1. The first opening 299-1 may face, or may be opposite to, the first side plate 261 described above.

The heat dissipation layer 200 may have a second opening 299-2 between one edge of the first intermediate plate 252-1 and one edge of the second intermediate plate 252-2. In other words, the second opening 299-2 may be located between one edge of the first intermediate plate 252-1 and one edge of the second intermediate plate 252-2. The second opening 299-2 may face, or may be opposite to, the second side plate 262 described above.

The heat dissipation layer 200 may have a third opening 299-3 between the other edge of the second intermediate plate 252-2 and the other edge of the upper plate 253 described above. In other words, the third opening 299-3 may be located between the other edge of the second intermediate plate 252-2 and the other edge of the upper plate 253. The third opening 299-3 may face, or may be opposite to, the third side plate 263 described above.

The first chamber 211 may be located between the lower plate 251 and the first intermediate plate 252-1 described above. For example, the first chamber 211 may be a region defined by being surrounded by the lower plate 251, the first intermediate plate 252-1, and the first side plate 261 in a (sideways) U shape. In addition, the first chamber 211 may be a structure including all of the lower plate 251, the first intermediate plate 252-1, the first side plate 261, and the space surrounded by them.

The second chamber 212 may be located between the first intermediate plate 252-1 and the second intermediate plate 252-2 described above. For example, the second chamber 212 may be a region defined by being surrounded by the first intermediate plate 252-1, the second intermediate plate 252-2, and the second side plate 262 in a (sideways) U shape. Further, the second chamber 212 may be a structure including all of the first intermediate plate 252-1, the second intermediate plate 252-2, the second side plate 262, and the space surrounded by them.

The third chamber 213 may be located between the second intermediate plate 252-2 and the upper plate 253 described above. For example, the third chamber 213 may be a region defined by being surrounded by the second intermediate plate 252-2, the upper plate 253, and the third side plate 263 in a (sideways) U shape. In addition, the third chamber 213 may be a structure including all of the second intermediate plate 252-2, the upper plate 253, the third side plate 263, and the space surrounded by them.

The support 280 may be located in at least one chamber. For example, the support 280 may be located in the second chamber 212 between the first intermediate plate 252-1 and the second intermediate plate 252-2. When the support 280 is located in the second chamber 212, the support 280 may extend from the bottom surface of the second intermediate plate 252-2 in the third reverse direction. The support 280 may have a through hole 297 penetrating in a direction (e.g., the first direction DR1 and/or the second direction DR2) perpendicular to the extension direction of the support 280.

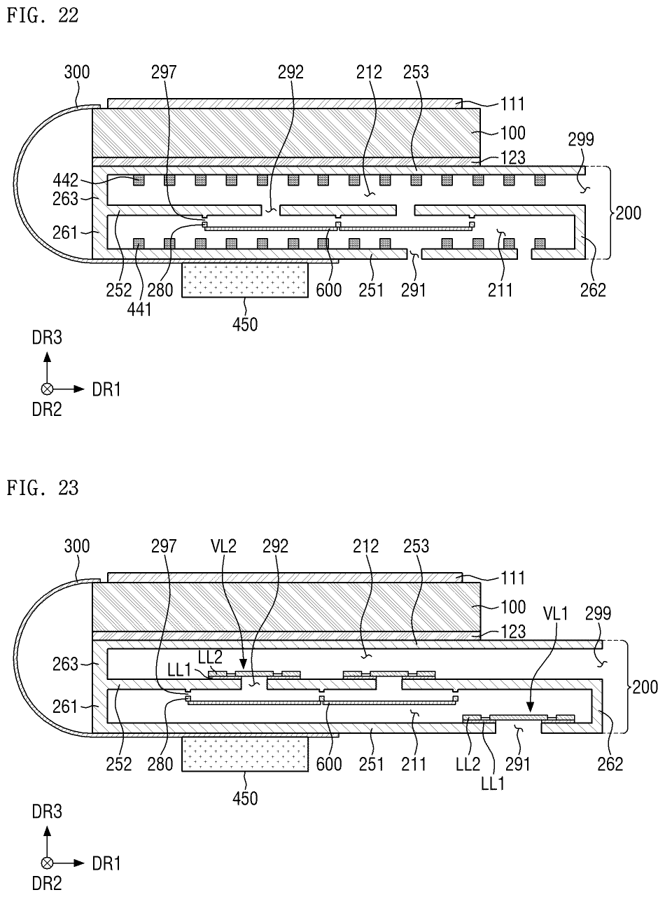

FIG. 22 is a cross-sectional view of the display device 10 according to one or more embodiments.

The display device 10 illustrated in FIG. 22 is different from the display device 10 of FIG. 10 described above in that it further includes at least one protrusion. The following description will mainly focus on this difference.

Referring to FIG. 22, the heat dissipation layer 200 may include at least one protrusion.

The protrusion may be located in at least one chamber. As in the example shown in FIG. 22, the protrusion may include one or more first protrusions 441 and one or more second protrusions 442. The first protrusion 441 may be located in the first chamber 211, and the second protrusion 442 may be located in the second chamber 212.

The first protrusion 441 may be located on the top surface of the lower plate 251. The first protrusion 441 may have a rectangular bar shape that protrudes from the top surface of the lower plate 251 in the third direction DR3. For example, the first protrusion 441 may have a rectangular bar shape (or a rectangular pillar shape) extending in the second direction DR2. When the first protrusions 441 is provided in plural number, the plurality of first protrusions 441 may be spaced apart from each other in the first direction DR1. The distance between the first protrusions 441 may be constant or different.

The second protrusion 442 may be located on the bottom surface of the upper plate 253. The second protrusion 442 may have a rectangular bar shape that protrudes from the bottom surface of the upper plate 253 in the third reverse direction. For example, the second protrusion 442 may have a rectangular bar shape (or a rectangular pillar shape) extending in the second direction DR2. When the second protrusion 442 is provided in plural number, the plurality of second protrusions 442 may be spaced apart from each other in the first direction DR1. The distance between the second protrusions 442 may be constant or different.

The plurality of first protrusions 441 and the plurality of second protrusions 442 may correspond to each other. For example, the number of the first protrusions 441 may be the same as the number of the second protrusions 442. In this case, the first protrusions 441 may face, or may be opposite to, the second protrusions 442, respectively.

In one or more embodiments, at least one of the first protrusion 441 or the second protrusion 442 may include a copper fiber.

The first protrusion 441 and the second protrusion 442 may increase the surface area of the first chamber 211 and the second chamber 212 of the heat dissipation layer 200. Accordingly, the heat dissipation effect of the heat dissipation layer 200 may be improved.

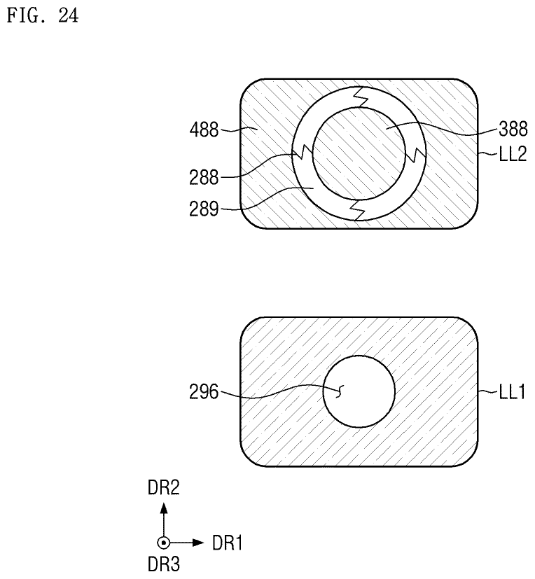

FIG. 23 is a cross-sectional view of the display device 10 according to one or more embodiments. FIG. 24 is an exploded plan view of a first valve VL1 of FIG. 23.

The display device 10 shown in FIG. 23 is different from the display device 10 of FIG. 10 described above in that it further includes at least one valve. The following description will mainly focus on this difference.

The valve may include at least one first valve VL1 and at least one second valve VL2.

The first valve VL1 may be located in the first chamber 211. For example, the first valve VL1 may be located on the top surface of the lower plate 251 in the first chamber 211. In this case, the first valve VL1 may be located on the top surface of the lower plate 251 to overlap the through hole(s) 291 of the lower plate 251.

Referring to FIG. 24, the first valve VL1 may include a first layer LL1 and a second layer LL2.

The first layer LL1 of the first valve VL1 may be located on the top surface of the lower plate 251. The first layer LL1 has a through hole 296 penetrating the first layer in the third direction DR3 so that the through hole 296 of the first layer may overlap the through hole(s) 291 of the lower plate 251.

The second layer LL2 of the first valve VL1 may be located on the first layer LL1. The second layer LL2 may include a body portion 488, a cover portion 388, and a connection portion 288.

The body portion 488 of the second layer LL2 may have a through hole 289 penetrating the body portion 488. The through hole 289 may have a circular shape.

The cover portion 388 of the second layer LL2 may be located in the through hole 289 of the body portion 488. The cover portion 388 may have a circular shape. The cover portion 388 may overlap the through hole 289 of the body portion 488. The cover portion 388 may have a larger diameter than the through hole 289 of the body portion 488. For example, the cover portion 388 may have a size that is sufficient to completely cover the through hole 289 of the body portion 488.

The connection portion of the second layer LL2 may connect the cover portion 388 to the body portion 488. The connection portion 288 may have a variable length.

The second valve VL2 may be located in the second chamber 212. For example, the second valve VL2 may be located on the top surface of the intermediate plate 252 in the second chamber 212. In this case, the second valve VL2 may be located on the top surface of the intermediate plate 252 to overlap the through hole(s) 292 of the intermediate plate 252. Further, the second valve VL2 may also overlap the piezoelectric element 600.

As shown in FIG. 23, the second valve VL2 may include the first layer LL1 and the second layer LL2.

The first layer LL1 of the second valve VL2 may be located on the top surface of the intermediate plate 252. The first layer LL1 of the second valve VL2 has a through hole penetrating the first layer LL1 of the second valve VL2 in the third direction DR3 so that the thorough hole of the first layer LL1 of the second valve VL2 may overlap the through hole(s) 292 of the intermediate plate 252.

The first layer LL1 and the second layer LL2 of the second valve VL2 may be the same as the first layer LL1 and the second layer LL2 of the first valve VL1 of FIG. 24, respectively.

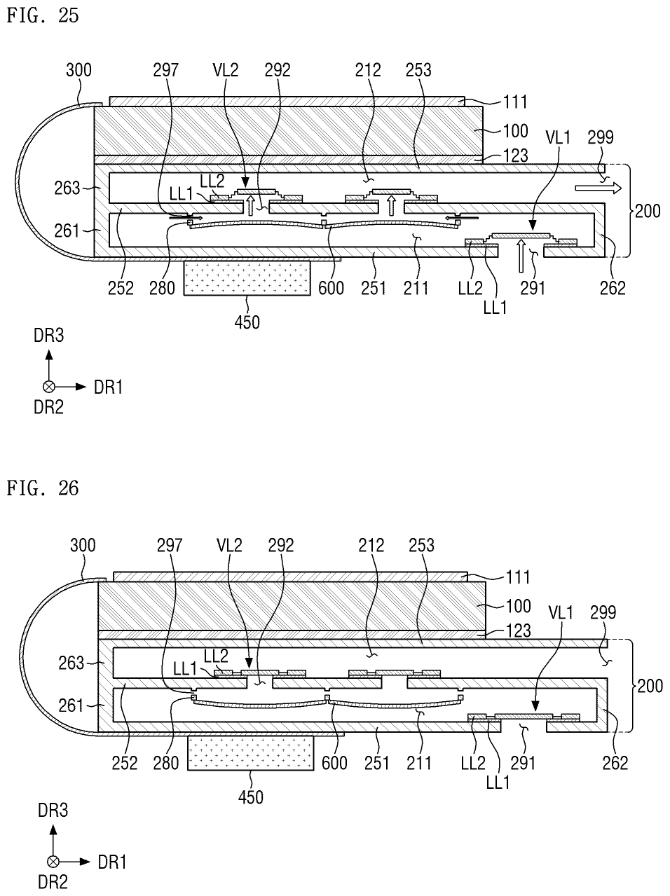

FIGS. 25 and 26 are diagrams for explaining the operation of the display device 10 of FIG. 23.

First, as shown in FIG. 25, when the piezoelectric element 600 is transformed to have a parabolic shape convex in the third direction DR3, the pressure of the first chamber 211 becomes lower than the pressure outside the heat dissipation layer 200 so that the first valve VL1 may be opened. For example, as the pressure of the first chamber 211 becomes lower than the pressure outside the heat dissipation layer 200, the cover portion of the first valve VL1 moves up in the third direction DR3 so that the first valve VL1 may be opened. As the first valve VL1 is opened, the air outside the heat dissipation layer 200 may be introduced into the first chamber 211 through the through hole(s) 291 of the lower plate 251. Then, the pressure of the first chamber 211 increases, and therefore, the pressure of the first chamber 211 may become higher than the pressure of the second chamber 212. Accordingly, the second valve VL2 may be opened. For example, as the pressure of the first chamber 211 becomes higher than the pressure of the second chamber 212, the cover portion of the second valve VL2 moves up in the third direction DR3 so that the second valve VL2 may be opened. As the second valve VL2 is opened, the air in the first chamber 211 may be introduced into the second chamber 212 through the through hole(s) 292 of the intermediate plate 252. Then, the pressure of the second chamber 212 increases and thus, the pressure of the second chamber 212 may become higher than the pressure outside the heat dissipation layer 200. Accordingly, the air introduced into the second chamber 212 may be discharged to the outside of the heat dissipation layer 200 through the opening 299. For example, along the directions indicated by the arrows shown in FIG. 25, external air introduced into the heat dissipation layer 200 may pass through the through hole(s) 291 of the lower plate 251, the first chamber 211, the through hole(s) 292 of the intermediate plate 252, the second chamber 212, and the opening 299 to be discharged to the outside of the heat dissipation layer 200. In other words, the air outside the heat dissipation layer 200 may be introduced into the heat dissipation layer 200 through the through hole(s) 291 of the lower plate 251, and then may be discharged to the outside through the opening 299 of the heat dissipation layer 200. Accordingly, the hot air in the first chamber 211 and the second chamber 212 may be discharged to the outside. Therefore, heat of the driving circuit 450 and the display panel 100 is easily released to the outside so that the heat may be effectively dissipated from the display device 10.

Meanwhile, as shown in FIG. 26, when the piezoelectric element 600 is transformed to have a parabolic shape convex in the third reverse direction, the pressure of the second chamber 212 becomes higher than the pressure of the first chamber 211 so that the second valve VL2 may be closed. Also, in this case, the pressure of the first chamber 211 becomes higher than the pressure outside the heat dissipation layer 200 so that the first valve VL1 may also be closed.

As shown in FIGS. 25 and 26, as the piezoelectric element 600 is alternately transformed along the third direction DR3 and the third reverse direction, air circulation occurs more actively in the heat dissipation layer 200. Accordingly, the heat dissipation of the display device 10 may be more effectively carried out.

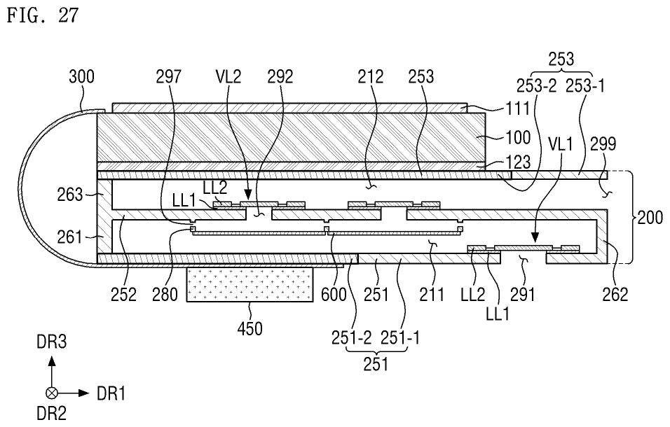

FIG. 27 is a cross-sectional view of the display device 10 according to one or more embodiments.

The display device 10 shown in FIG. 27 is different from the display device 10 of FIG. 23 described above in that at least two parts of the heat dissipation layer 200 are made of different materials. The following description will mainly focus on this difference.

Referring to FIG. 27, the lower plate 251 of the heat dissipation layer 200 may include sub-lower plates 251-1 and 251-2 made of different materials. For example, the lower plate 251 may include a first sub-lower plate 251-1 made of a first material, and a second sub-lower plate 251-2 made of a second material. The first sub-lower plate 251-1 and the second sub-lower plate 251-2 may be arranged in the first direction DR1. The first sub-lower plate 251-1 may be connected to the second sub-lower plate 251-2. One edge of the second sub-lower plate 251-2 may be connected to the first side plate 261, and the other edge of the second sub-lower plate 251-2 may be connected to one edge of the first sub-lower plate 251-1. The second sub-lower plate 251-2 made of the second material may overlap the driving circuit 450, for example. Here, for example, the first material may be plastic and the second material may be metal. In one or more embodiments, the second material may be plastic or metal.

The upper plate 253 may include a first sub-upper plate 253-1 made of a first material, and a second sub-upper plate 253-2 made of a second material. The first sub-upper plate 253-1 and the second sub-upper plate 253-2 may be arranged in the first direction DR1. The first sub-upper plate 253-1 may be connected to the second sub-upper plate 253-2. One edge of the second sub-upper plate 253-2 may be connected to the third side plate 263, and the other edge of the second sub-upper plate 253-2 may be connected to one edge of the first sub-upper plate 253-1. The second sub-upper plate 253-2 made of the second material may overlap the display panel 100, for example. Here, for example, the first material may be plastic and the second material may be metal.

As such, when portions of the heat dissipation layer 200, which are adjacent to the driving circuit 450 and the display panel 100 serving as heating elements in the third direction DR3, and which overlap the driving circuit 450 and the display panel 100, are made of a metal material, heat from the driving circuit 450 and the display panel 100 may be more effectively transferred to the heat dissipation layer 200, and thus the heat dissipation of the display device 10 may be more effectively carried out.

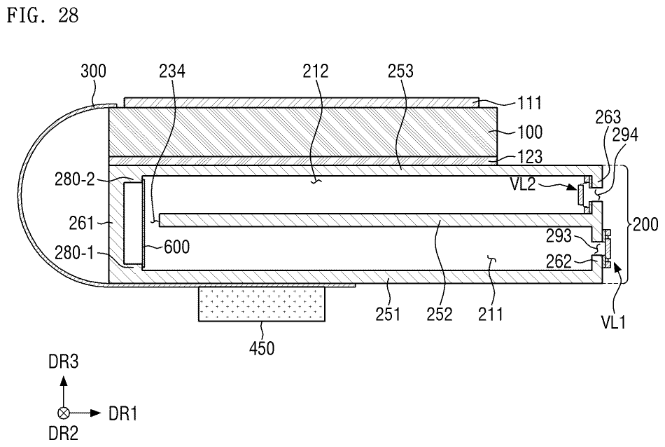

FIG. 28 is a cross-sectional view of the display device 10 according to one or more embodiments.

The display device 10 shown in FIG. 28 is different from the display device 10 of FIG. 10 described above in the structure of the heat dissipation layer 200. The following description will mainly focus on this difference.

The heat dissipation layer 200 may include the lower plate 251, the intermediate plate 252, the upper plate 253, the first side plate 261, the second side plate 262, the third side plate 263, a plurality of supports 280-1 and 280-2, the plurality of chambers 211 and 212, the piezoelectric element 600, and the plurality of valves VL1 and VL2. Here, each of the aforementioned chambers 211 and 212 or the space of each of the chambers 211 and 212 may be defined by the lower plate 251, the intermediate plate 252, the upper plate 253, the first side plate 261, the second side plate 262, and the third side plate 263.

The lower plate 251, the intermediate plate 252, the upper plate 253, the first side plate 261, the second side plate 262, the third side plate 263 and the plurality of supports 280-1 and 280-2 described above may be integrally formed.

The lower plate 251 may be located above the driving circuit 450. For example, the lower plate 251 may be located above the driving circuit 450 in the third direction DR3 to overlap the driving circuit 450. The lower plate 251 may have a rectangular shape extending in the first direction DR1. The lower plate 251 may be in contact with the circuit board 300.

The intermediate plate 252 may be located above the lower plate 251. For example, the intermediate plate 252 may be located above the lower plate 251 in the third direction DR3 to overlap the lower plate 251. In this case, the intermediate plate 252 may be located between the lower plate 251 and the upper plate 253. The intermediate plate 252 may overlap the lower plate 251 and the upper plate 253. The intermediate plate 252 may have a rectangular shape extending in the first direction DR1.

The upper plate 253 may be located above the intermediate plate 252. For example, the upper plate 253 may be located above the intermediate plate 252 in the third direction DR3 to overlap the intermediate plate 252. The upper plate 253 may have a rectangular shape extending in the first direction DR1. The upper plate 253 may be in contact with the heat conduction layer 123.

The first side plate 261 may be located on one edge of the lower plate 251. The first side plate 261 may have a rectangular shape extending from one edge of the lower plate 251 in the third direction DR3. The first side plate 261 may be located between, for example, one edge of the lower plate 251 and one edge of the upper plate 253. The first side plate 261 may be connected to one edge of the lower plate 251 and one edge of the upper plate 253. The first side plate 261 may face, or may be opposite to, the piezoelectric element 600 in the first direction DR1. The first side plate 261 may be spaced apart from the intermediate plate 252 in the first direction DR1.

The second side plate 262 may be located on the other edge of the lower plate 251. The second side plate 262 may have a rectangular shape extending from the other edge of the lower plate 251 in the third direction DR3. The second side plate 262 may be located between, for example, the other edge of the lower plate 251 and the other edge of the intermediate plate 252. The second side plate 262 may be connected to the other edge of the lower plate 251 and the other edge of the intermediate plate 252. The second side plate 262 may face, or may be opposite to, the piezoelectric element 600. The second side plate 262 may have the through hole 293 penetrating in a direction (e.g., the first direction DR1) perpendicular to the extension direction thereof.

The third side plate 263 may be located on the other edge of the intermediate plate 252. The third side plate 263 may have a rectangular shape extending from the other edge of the intermediate plate 252 in the third direction DR3. The third side plate 263 may be located between, for example, the other edge of the intermediate plate 252 and the other edge of the upper plate 253. The third side plate 263 may be connected to the other edge of the intermediate plate 252 and the other edge of the upper plate 253. The third side plate 263 may have the through hole 294 penetrating in a direction (e.g., the first direction DR1) perpendicular to the extension direction thereof.

The first chamber 211 may be located between the lower plate 251 and the intermediate plate 252 described above. For example, the first chamber 211 may be a region defined by being surrounded by the lower plate 251, the intermediate plate 252, the first side plate 261, and the second side plate 262. Further, the first chamber 211 may be a structure including all of the lower plate 251, the intermediate plate 252, the first side plate 261, the second side plate 262, and the space surrounded by them.

The second chamber 212 may be located between the intermediate plate 252 and the upper plate 253 described above. For example, the second chamber 212 may be a region defined by being surrounded by the intermediate plate 252, the upper plate 253, the first side plate 261, and the third side plate 263. In addition, the second chamber 212 may be a structure including all of the intermediate plate 252, the upper plate 253, the first side plate 261, the third side plate 263, and the space surrounded by them.

The first chamber 211 may communicate with the second chamber 212 through an opening 234 between the piezoelectric element 600 and one edge of the intermediate plate 252.

The first support 280-1 may be located in the first chamber 211. For example, the first support 280-1 may be located around a connection portion between the lower plate 251 and the first side plate 261. The first support 280-1 may extend from one edge (e.g., the lower edge) of the first side plate 261 in the first direction DR1.

The second support 280-2 may be located in the second chamber 212. For example, the second support 280-2 may be located around a connection portion between the upper plate 253 and the first side plate 261. The second support 280-2 may extend from the other edge (e.g., the upper edge) of the first side plate 261 in the first direction DR1.

The piezoelectric element 600 may be located on the first support 280-1 and the second support 280-2. For example, one edge of the piezoelectric element 600 may be located on the first support 280-1, and the other edge of the piezoelectric element 600 may be located on the second support 280-2. The opening 234 may be located between the piezoelectric element 600 and the intermediate plate 252. The first chamber 211 and the second chamber 212 described above may communicate with each other through the opening 234. In one or more embodiments, the piezoelectric element 600 may be fixed on the supports 280-1 and 280-2 via fixing means coupled to the supports 280-1 and 280-2.

The piezoelectric element 600 may be transformed according to a voltage from the outside. For example, depending on the direction of the current flowing through the piezoelectric element 600, the piezoelectric element 600 is transformed to be convex in the first direction DR1 or in a reverse direction to the first direction DR1 (hereinafter, referred to as a first reverse direction). For example, according to the aforementioned current direction, the piezoelectric element 600 may be transformed to have a parabolic shape convex in the first direction DR1 or a parabolic shape convex in the first reverse direction.

The first valve VL1 may be located on the second side plate 262 outside the heat dissipation layer 200. For example, the first layer LL1 of the first valve VL1 may be located on the outer surface of the second side plate 262, and the second layer LL2 of the first valve VL1 may be located on the first layer LL1 of the first valve VL1. Also, the first valve VL1 may be located on the outer surface of the second side plate 262 to overlap the through hole 293 of the second side plate 262.

The second valve VL2 may be located on the third side plate 263 in the second chamber 212. For example, the first layer LL1 of the second valve VL2 may be located on the inner surface of the third side plate 263, and the second layer LL2 of the second valve VL2 may be located on the first layer LL1 of the second valve VL2. Further, the second valve VL2 may be located on the inner surface of the third side plate 263 to overlap the through hole 294 of the third side plate 263.

The first valve VL1 and the second valve VL2 may operate in opposition to each other. For example, when the first valve VL1 is opened, the second valve VL2 may be closed. Also, when the first valve VL1 is closed, the second valve VL2 may be opened.

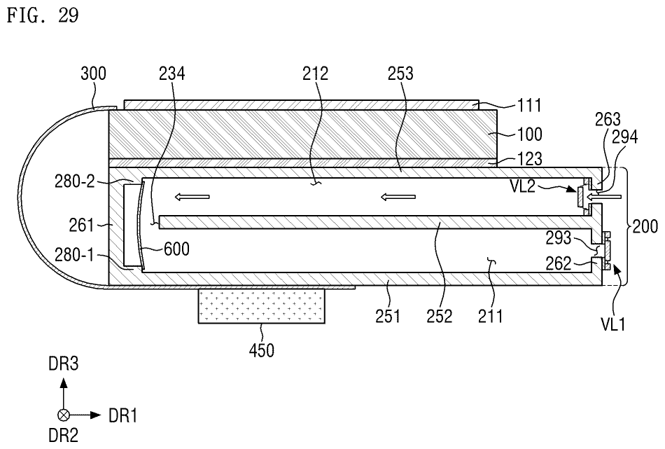

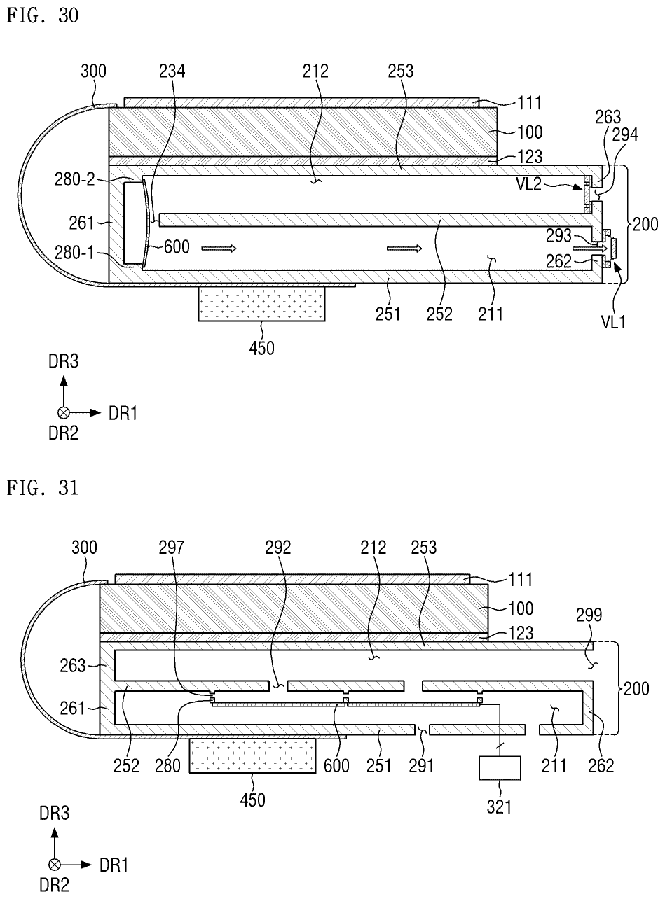

FIGS. 29 and 30 are diagrams for explaining the operation of the display device 10 of FIG. 28.

First, as shown in FIG. 29, when the piezoelectric element 600 is transformed to have a parabolic shape convex in the first reverse direction, the pressure of the first chamber 211 and the second chamber 212 becomes lower than the pressure outside the heat dissipation layer 200 so that the first valve VL1 may be closed, while the second valve VL2 may be opened. For example, as the pressure of the first chamber 211 and the second chamber 212 becomes lower than the pressure outside the heat dissipation layer 200, the cover portion of the first valve VL1 moves down in the first reverse direction, thereby closing the first valve VL1, while the cover portion of the second valve VL2 moves up in the first reverse direction, thereby opening the second valve VL2. Then, the air outside the heat dissipation layer 200 is introduced into the second chamber 212 through the opened second valve VL2 and the through hole 294 of the third side plate 263.

Subsequently, as shown in FIG. 30, when the piezoelectric element 600 is transformed to have a parabolic shape convex in the first direction DR1, the pressure of the first chamber 211 and the second chamber 212 becomes higher than the pressure outside the heat dissipation layer 200 so that the first valve VL1 may be opened, while the second valve VL2 may be closed. For example, as the pressure of the first chamber 211 and the second chamber 212 becomes higher than the pressure outside the heat dissipation layer 200, the cover portion of the first valve VL1 moves up in the first direction DR1, thereby opening the first valve VL1, while the cover portion of the second valve VL2 moves down in the first direction DR1, thereby closing the second valve VL2. Then, the air in the first chamber 211 and the second chamber 212 may be discharged to the outside of the heat dissipation layer 200 through the opened first valve VL1 and the through hole 293 of the second side plate 262.

For example, along the directions indicated by the arrows shown in FIGS. 29 and 30, the external air introduced into the heat dissipation layer 200 may pass through the through hole 294 of the third side plate 263, the second chamber 212, the opening 234, the first chamber 211, and the through hole 293 of the second side plate 262 sequentially to be discharged to the outside of the heat dissipation layer 200. In other words, the air outside the heat dissipation layer 200 may be introduced into the heat dissipation layer 200 through the through hole 294 of the third side plate 263 and may be discharged to the outside through the through hole 293 of the second side plate 262. Accordingly, the hot air in the first chamber 211 and the second chamber 212 may be discharged to the outside. Therefore, heat from the driving circuit 450 and the display panel 100 may be easily released to the outside so that the heat may be effectively dissipated from the display device 10.

As shown in FIGS. 29 and 30, as the piezoelectric element 600 is alternately transformed along the first reverse direction and the first direction DR1, air circulation occurs more actively in the heat dissipation layer 200. Accordingly, the heat dissipation of the display device 10 may be more effectively carried out.

FIG. 31 is a cross-sectional view of the display device 10 according to one or more embodiments.

The display device 10 shown in FIG. 31 is different from the display device 10 of FIG. 10 described above in that it further includes an external power supply 321. The following description will mainly focus on this difference.

Referring to FIG. 31, the piezoelectric element 600 may receive an AC voltage from the external power supply 321. The external power supply 321 may be located on a set board, for example. In this case, the piezoelectric element 600 may be connected to the external power supply 321 via the set board.

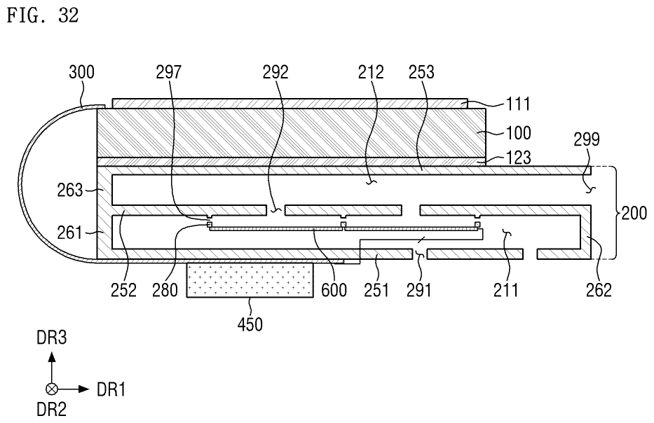

FIG. 32 is a cross-sectional view of the display device 10 according to one or more embodiments.

The display device 10 shown in FIG. 32 is different from the display device 10 of FIG. 31 described above in supplying power to the piezoelectric element 600. The following description will mainly focus on this difference.

Referring to FIG. 32, the piezoelectric element 600 may receive an AC voltage from, for example, the driving circuit 450 instead of the aforementioned external power supply 321. To this end, in one or more embodiments, the piezoelectric element 600 may be connected to the driving circuit 450 via the circuit board 300. For example, the piezoelectric element 600 may be connected to the timing control circuit 400 or the power supply circuit 500 of the driving circuit 450 via the circuit board 300. In this case, the timing control circuit 400 or the power supply circuit 500 may provide an AC voltage.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a driving circuit;
a display panel above the driving circuit along a first direction; and
a heat dissipation layer between the driving circuit and the display panel, and comprising chambers, and a piezoelectric element in at least one of the chambers the piezoelectric element being configured to be transformed along the first direction or a reverse direction to the first direction.

2. The display device of claim 1, wherein the heat dissipation layer further comprises:
a lower plate adjacent to the driving circuit;
an upper plate adjacent to the display panel; and
an intermediate plate between the lower plate and the upper plate, and defining a through hole.

3. The display device of claim 2, wherein the chambers comprise:
a first chamber between the lower plate and the intermediate plate; and
a second chamber between the intermediate plate and the upper plate.

4. The display device of claim 3, wherein the lower plate defines a through hole penetrating the lower plate, and
wherein the heat dissipation layer further comprises:
a first side plate connecting one edge of the lower plate to one edge of the intermediate plate;
a second side plate connecting another edge of the lower plate to another edge of the intermediate plate;
a third side plate connecting the one edge of the intermediate plate to one edge of the upper plate; and
an opening between the other edge of the intermediate plate and another edge of the upper plate.

5. The display device of claim 4, wherein the piezoelectric element overlaps the through hole of the intermediate plate.

6. The display device of claim 1, wherein the heat dissipation layer further comprises a support in at least one of the chambers to support the piezoelectric element.

7. The display device of claim 6, wherein the support defines a through hole penetrating the support in a second direction substantially perpendicular to the first direction.

8. The display device of claim 1, further comprising a heat conduction layer between the display panel and the heat dissipation layer.

9. The display device of claim 8, further comprising a metal layer between the heat conduction layer and the heat dissipation layer.

10. The display device of claim 1, further comprising a circuit board between the driving circuit and the heat dissipation layer.

11. The display device of claim 4, wherein the heat dissipation layer further comprises:
a first protrusion defined by the lower plate in the first chamber; and
a second protrusion defined by the upper plate in the second chamber.

12. The display device of claim 4, wherein the heat dissipation layer further comprises:
a first valve in the first chamber to overlap a through hole of the lower plate; and
a second valve in the second chamber to overlap the through hole of the intermediate plate.

13. The display device of claim 12, wherein the second valve overlaps the piezoelectric element.

14. The display device of claim 4, wherein the lower plate comprises sub-lower plates comprising different respective materials, and
wherein the upper plate comprises sub-upper plates comprising different respective materials.

15. The display device of claim 14, wherein one of the sub-lower plates overlapping the driving circuit comprises a metal material,
wherein a remaining one or more of the sub-lower plates comprises a plastic material,
wherein one of the sub-upper plates overlapping the display panel comprises a metal material, and
wherein a remaining one or more of the sub-upper plates comprises a plastic material.

16. The display device of claim 3, wherein the heat dissipation layer further comprises a first side plate connecting another edge of the lower plate to another edge of the intermediate plate, and a second side plate connecting one edge of the intermediate plate to one edge of the upper plate; and
wherein the heat dissipation layer defines a first opening between one edge of the lower plate and one edge of the intermediate plate, and a second opening between another edge of the intermediate plate and another edge of the upper plate.

17. The display device of claim 3, wherein the heat dissipation layer further comprises:
a first side plate connecting one edge of the lower plate to one edge of the intermediate plate;
a second side plate connecting another edge of the lower plate to another edge of the intermediate plate, and defining a through hole;
a third side plate connecting one edge of the intermediate plate to one edge of the upper plate; and
a fourth side plate connecting the other edge of the intermediate plate to another edge of the upper plate, and defining a through hole.

18. The display device of claim 2, wherein the intermediate plate comprises:
a first intermediate plate between the lower plate and the upper plate, and defining a through hole; and
a second intermediate plate between the first intermediate plate and the upper plate, and defining a through hole.

19. The display device of claim 18, wherein the chambers comprise:
a first chamber between the lower plate and the first intermediate plate;
a second chamber between the first intermediate plate and the second intermediate plate; and
a third chamber between the second intermediate plate and the upper plate.

20. The display device of claim 19, wherein the heat dissipation layer further comprises:
a first side plate connecting one edge of the lower plate to one edge of the intermediate plate;
a second side plate connecting another edge of the first intermediate plate to another edge of the second intermediate plate;
a third side plate connecting one edge of the second intermediate plate to one edge of the upper plate, and
wherein the heat dissipation layer defines:
a first opening between another edge of the lower plate and the other edge of the first intermediate plate;
a second opening between one edge of the first intermediate plate and the one edge of the second intermediate plate; and
a third opening between the other edge of the second intermediate plate and another edge of the upper plate.

21. The display device of claim 1, wherein the piezoelectric element is connected to an external power supply.

22. The display device of claim 1, wherein the piezoelectric element is connected to the driving circuit.
